(19) United States
(12) Patent Application Publication
(10) Pub. No.: US 2026/0143856 A1
(43) Pub. Date: May 21, 2026

(54) SEMICONDUCTOR PACKGAGE AND CAMERA MODULE

(71) Applicant: Samsung Electronics Co., Ltd., Suwon-si (KR)

(72) Inventors: Tsuyoshi OGAWA, Yokohama-shi (JP); Kazutaka HONDA, Yokohama-shi (JP)

(73) Assignee: Samsung Electronics Co., Ltd., Suwon-si (KR)

(21) Appl. No.: 19/308,440

(22) Filed: Aug. 25, 2025

(30) Foreign Application Priority Data
Nov. 19, 2024 (JP) 2024-201268
Apr. 17, 2025 (KR) 10-2025-0050486

(51) Int. Cl. H10F 77/00; H10F 39/18; H10F 71/00; H10F 77/50

(52) U.S. Cl. CPC H10F 77/933; H10F 39/182; H10F 71/00; H10F 77/50

(57) ABSTRACT

A semiconductor package may include a first semiconductor chip including a chip substrate, the chip substrate having a first surface and a second surface opposite to the first surface, the first semiconductor chip including an electrode on the first surface and a through-hole extending from the second surface to the first surface to expose the electrode, a first redistribution layer on the second surface of the chip substrate, one or more first passive components electrically connected to the first redistribution layer, a columnar electrode electrically connected to the first redistribution layer, and an encapsulating resin layer covering the second surface of the chip substrate, and the one or more first passive components may be disposed in a position lower than a level of the columnar electrode with respect to the first redistribution layer, and may be covered by an encapsulating resin layer.

### CROSS-REFERENCE TO RELATED APPLICATION(S)

This application claims benefit of priority to Korean Patent Application No. 10-2025-0050486 filed on Apr. 17, 2025 in the Korean Intellectual Property Office and Japanese Patent Application No. 2024-201268 filed on Nov. 19, 2024 in the Japan Patent Office, the disclosures of which are incorporated herein by reference in their entirety.

### BACKGROUND

Example embodiments of the present disclosure relate to semiconductor packages and/or camera modules.

Recently, to cope with miniaturization and higher integration of semiconductor chips, flip chip mounting using a semiconductor package as a chip scale package (CSP) has been actively adopted.

A size of a package size of a chip scale package may be approximately the same as that of a semiconductor chip, miniaturization may be possible, such that productivity of a wafer-level process may be favorable, but relatively low reliability of solder connection in package mounting may be a disadvantage. In package mounting of chip scale package, relatively low reliability of solder joint may be due to a difference between a coefficient of linear expansion (about 3 ppm/° C. or lower) of silicon, which may be a base material of chip scale package forming a chip substrate of a semiconductor chip, and a coefficient of linear expansion (about 15 to 20 ppm/° C.) of the mounting substrate such as a motherboard on which the chip scale package is mounted. Stress applied to a connection terminal and the periphery thereof may increase due to a difference in thermal expansion in response to temperature changes such as temperature cycles.

In a device (or a semiconductor package) including a redistribution layer, a stress relieving layer (e.g., stress alleviating layer) disposed between a covering layer, which is stacked on an insulating layer covering a wiring layer formed on a semiconductor chip, and the redistribution layer to alleviate stress applied to a semiconductor device and a post for relieving stress applied to a connection terminal may be applied to address issues resulting from such stress.

In such a semiconductor package, the stress alleviating layer may be disposed below the redistribution layer, but stress alleviation effect of the stress alleviating layer alone may be somewhat limited. Furthermore, the semiconductor package may further include a post including a connection terminal that is directly disposed with respect to the redistribution layer formed on a surface side, and accordingly, and thus stress applied to the connection terminal may be directly transmitted to the redistribution layer, thereby causing damage to the redistribution layer. Accordingly, solder joint reliability of such device needs to be improved.

Such a semiconductor package may be mounted on a camera module. In addition to the semiconductor package, the camera module may include various peripheral components including passive components such as power capacitors mounted thereon. The peripheral components may be disposed around the semiconductor package due to the structure of the module. Accordingly, in a general camera module, the module may be enlarged to ensure a mounting region for a peripheral component, which may be problematic. Also, properties of the peripheral component may deteriorate due to parasitic capacitance of a wiring disposed between the semiconductor packages when the peripheral component is disposed in a position separated from the semiconductor package.

### SUMMARY

Some example embodiments of the present disclosure may provide semiconductor packages and/or camera modules including the semiconductor package which may improve solder joint reliability accompanying temperature changes when a semiconductor package is mounted, may reduce a module size of the camera module on which the semiconductor package is mounted, and may obtain good electrical properties with passive components mounted on the camera module.

According to an example embodiment of the present disclosure, a semiconductor package includes a first semiconductor chip including a chip substrate, the chip substrate including a first surface and a second surface opposite to the first surface, the first semiconductor chip including an electrode on the first surface and a through-hole extending from the second surface to the first surface to expose the electrode, a first redistribution layer on the second surface of the chip substrate, the first redistribution layer being in the through-hole and electrically connected to the electrode, the first redistribution layer including a third surface facing the first semiconductor chip and a fourth surface opposite to the third surface, one or more first passive components electrically connected to the first redistribution layer, each of the one or more first passive components including a fifth surface facing the first redistribution layer and a sixth surface opposite to the first surface, a columnar electrode electrically connected to the first redistribution layer, the columnar electrode including a seventh surface facing the first redistribution layer and an eighth surface opposite to the seventh surface, and an encapsulating resin layer covering the second surface of the chip substrate, wherein the columnar electrode is on the fourth surface of the first redistribution layer, and wherein the sixth surface of each of the one or more first passive components is at a position lower than the eighth surface of the columnar electrode with respect to the fourth surface of the first redistribution layer and is covered by the encapsulating resin layer.

When the one or more first passive components include one type of passive component having a first height and another type of passive component having a second height greater than the first height, the one type of passive component may be on an outer circumferential portion of the first semiconductor chip.

A second semiconductor chip may be on the fourth surface of the first redistribution layer.

The semiconductor package may further include a second redistribution layer on an external surface of the encapsulating resin layer and electrically connected to the columnar electrode, the second redistribution layer including a nineth surface facing the first semiconductor chip and a tenth surface opposite to the nineth surface, and a plurality of connection terminals on the tenth surface.

The semiconductor package may further include a package substrate electrically connected to the columnar electrode, the package substrate including an eleventh surface and a twelfth surface opposite to the eleventh surface, and a connection terminal on the twelfth surface of the package substrate, wherein the package substrate includes an insulating portion and an internal wiring portion in the insulating portion, wherein the internal wiring portion has a first connection portion exposed to the eleventh surface of the package substrate, and a second connection portion exposed to the twelfth surface of the package substrate, and wherein the internal wiring portion is electrically connected to the columnar electrode through the first connection portion and is electrically connected to the connection terminal through the second connection portion.

The semiconductor package may further include one or more second passive components on the eleventh surface of the package substrate and connected to the internal wiring portion.

The one or more second passive components may include one type of passive component having a first height and another type of passive component having a second height greater than the first height, and the one type of passive component on an outer circumferential portion of the first semiconductor chip.

A third semiconductor chip may be on the eleventh surface of the package substrate.

The columnar electrode may adhere to the first redistribution layer with the first conductive portion interposed therebetween.

A first elastic modulus of the first conductive portion may be lower than a second elastic modulus of the columnar electrode.

The columnar electrode may include a metal pin or a plated metal.

The encapsulating resin layer may include a non-conductive filler.

A first coefficient of linear expansion of the encapsulating resin layer may be equal to or higher than a second coefficient of linear expansion of the chip substrate of the first semiconductor chip.

The first conductive portion may include conductive paste or solder.

The first semiconductor chip may be an image sensor.

According to an example embodiment of the present disclosure, a camera module includes the aforementioned semiconductor package, and an optical unit having at least one lens unit on a side of the semiconductor package to which the light is incident.

According to an example embodiment of the present disclosure, a semiconductor package includes a first semiconductor chip including a chip substrate, the chip substrate including a first surface and a second surface opposite to the first surface, the first semiconductor chip including an electrode on the first surface and a through-hole extending from the second surface to the first surface to expose the electrode, a first redistribution layer on the second surface of the chip substrate, the first redistribution layer being in the through-hole and electrically connected to the electrode, the first redistribution layer including a third surface facing the first semiconductor chip and a fourth surface opposite to the third surface, one or more passive components on the fourth surface of the first redistribution layer and electrically connected to the first redistribution layer, a columnar electrode on the fourth surface of the first redistribution layer and electrically connected to the first redistribution layer, and an encapsulating resin layer on the second surface of the chip substrate, wherein a first height of each of the one or more passive components is less than a second height of the columnar electrode and the encapsulating resin layer covers the one or more passive components and surrounds the columnar electrode.

The one or more passive components may include a first passive component having a first height on a central portion of the first semiconductor chip and a second passive component having a second height greater than the first height on an outer circumferential portion of the first semiconductor chip.

The semiconductor package may further include a connection terminal in physical contact with the columnar electrode exposed by the encapsulating resin layer.

The semiconductor package may further include a conductive portion interposed between and in direct contact with the columnar electrode and the first redistribution layer.

### BRIEF DESCRIPTION OF DRAWINGS

The above and other aspects, features, and advantages of the present disclosure will be more clearly understood from the following detailed description, taken in combination with the accompanying drawings, in which:

FIG. 1 may be a cross-sectional diagram illustrating a state in which a semiconductor package is mounted on a mounting substrate according to a first example embodiment of the present disclosure;

FIG. 2 is a cross-sectional diagram illustrating a semiconductor package according to the first example embodiment;

FIG. 3 is a flowchart illustrating a method of manufacturing a semiconductor package according to the first example embodiment;

FIG. 4A is a cross-sectional diagram illustrating process S1 of FIG. 3;

FIG. 4B is a cross-sectional diagram illustrating process S2 of FIG. 3;

FIG. 4C is a cross-sectional diagram illustrating process S3 of FIG. 3;

FIG. 4D is a cross-sectional diagram illustrating process S4 of FIG. 3;

FIG. 4E is a cross-sectional diagram illustrating process S5 of FIG. 3;

FIG. 4F is a cross-sectional diagram illustrating process S6 of FIG. 3;

FIG. 4G is a cross-sectional diagram illustrating process S7 of FIG. 3;

FIG. 4H is a cross-sectional diagram illustrating process S8 of FIG. 3;

FIG. 4I is a cross-sectional diagram illustrating process S9 of FIG. 3;

FIG. 4J is a cross-sectional diagram illustrating process S10 of FIG. 3;

FIG. 4K is a cross-sectional diagram illustrating process S11 of FIG. 3;

FIG. 4L is a cross-sectional diagram illustrating process S12 of FIG. 3;

FIG. 4M is a cross-sectional diagram illustrating process S13 of FIG. 3;

FIG. 5 is a cross-sectional diagram illustrating a modified example of the semiconductor package according to the first example embodiment;

FIG. 6 is a cross-sectional diagram illustrating another modified example of the semiconductor package according to the first example embodiment;

FIG. 7A is a cross-sectional diagram illustrating a semiconductor package according to a second example embodiment of the present disclosure;

FIG. 7B is a diagram illustrating an example of wiring of a first passive component mounted on a first redistribution layer of a semiconductor package according to the second example embodiment;

FIG. 8 is a flowchart illustrating a method of manufacturing a semiconductor package according to the second example embodiment;

FIG. 9A is a cross-sectional diagram illustrating process S21 of FIG. 8;

FIG. 9B is a cross-sectional diagram illustrating process S22 of FIG. 8;

FIG. 9C is a cross-sectional diagram illustrating process S23 of FIG. 8;

FIG. 9D is a cross-sectional diagram illustrating process S24 of FIG. 8;

FIG. 9E is a cross-sectional diagram illustrating process S25 of FIG. 8;

FIG. 9F is a cross-sectional diagram illustrating process S26 of FIG. 8;

FIG. 9G is a cross-sectional diagram illustrating process S27 of FIG. 8;

FIG. 9H is a cross-sectional diagram illustrating process S28 of FIG. 8;

FIG. 9I is a cross-sectional diagram illustrating process S29 of FIG. 8;

FIG. 9J is a cross-sectional diagram illustrating process S30 of FIG. 8;

FIG. 9K is a cross-sectional diagram illustrating process S31 of FIG. 8;

FIG. 9L is a cross-sectional diagram illustrating process S32 of FIG. 8;

FIG. 9M is a cross-sectional diagram illustrating process S33 of FIG. 8;

FIG. 9N is a cross-sectional diagram illustrating process S34 of FIG. 8;

FIG. 10 is a cross-sectional diagram illustrating a modified example of the semiconductor package according to the second example embodiment;

FIG. 11 is a cross-sectional diagram illustrating another modified example of the semiconductor package according to the second example embodiment;

FIG. 12 is a cross-sectional diagram illustrating a semiconductor package according to a third example embodiment of the present disclosure;

FIG. 13 is a flowchart illustrating a method of manufacturing a semiconductor package according to the third example embodiment;

FIG. 14A is a cross-sectional diagram illustrating process S41 of FIG. 13;

FIG. 14B is a cross-sectional diagram illustrating process S42 of FIG. 13;

FIG. 14C is a cross-sectional diagram illustrating process S43 of FIG. 13;

FIG. 14D is a cross-sectional diagram illustrating process S44 of FIG. 13;

FIG. 14E is a cross-sectional diagram illustrating process S45 of FIG. 13;

FIG. 14F is a cross-sectional diagram illustrating process S46 of FIG. 13;

FIG. 14G is a cross-sectional diagram illustrating process S47 of FIG. 13;

FIG. 14H is a cross-sectional diagram illustrating process S48 of FIG. 13;

FIG. 14I is a cross-sectional diagram illustrating process S49 of FIG. 13;

FIG. 14J is a cross-sectional diagram illustrating process S50 of FIG. 13;

FIG. 14K is a cross-sectional diagram illustrating process S51 of FIG. 13;

FIG. 14L is a cross-sectional diagram illustrating process S52 of FIG. 13;

FIG. 14M is a cross-sectional diagram illustrating process S53 of FIG. 13;

FIG. 14N is a cross-sectional diagram illustrating process S54 of FIG. 13;

FIG. 14O is a cross-sectional diagram illustrating process S55 of FIG. 13;

FIG. 15 is a cross-sectional diagram illustrating a semiconductor package of a modified example according to the third example embodiment;

FIG. 16 is a cross-sectional diagram illustrating a semiconductor package of another modified example according to the third example embodiment;

FIG. 17 is a cross-sectional diagram illustrating a semiconductor package of still another modified example according to the third example embodiment; and

FIG. 18 is a cross-sectional diagram illustrating an example of a camera module including a semiconductor package according to an example embodiment.

### DETAILED DESCRIPTION

Hereinafter, some example embodiments of the present disclosure will be described as below with reference to the accompanying drawings.

In the drawings, same elements will be indicated by same reference numerals. In the diagram, the size of each component is represented in a different ratio from the actual state for clarity and ease of description. The example embodiments described below are merely examples, and various modifications may be made from the example embodiments.

The terms “upper portion” or “on” or “above” may include “being in direct contact with the other and disposed thereon,” and also “disposed above by not being in contact.” Also, the terms “lower portion” or “below” may include “being in direct contact with the other and disposed below,” and also “disposed below by not being in contact.”

An expression used in the singular encompasses the expression of the plural, unless it has a clearly different meaning in the context. Also, the configuration in which a portion “includes” or “has” an element does not exclude that the other element is included and may indicate that the other element may be further included, unless otherwise indicated.

As for the processes included in the method, the order may be explicitly described or otherwise not indicated, the processes included in the method may be performed in an appropriate order but is not necessarily limited to the above-described order. The use of examples or example terms is intended merely to illustrate technical ideas and the scope thereof is not limited to the examples or example terms, unless otherwise limited by the scope of the claims.

Also, the terms “first,” “second,” and the like, may be used to distinguish one element from the other, and may not limit a sequence and/or an importance, or others, in relation to the elements.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “one of,” “one or more of,” “any one of,” “at least one of,” and “at least one selected from” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

Semiconductor package 1, 1A, 1B, 2, 2A, 2B, 3, 3A and 3B, and 3C illustrated may be a wafer-level package CSP including a first semiconductor chip 20 as a solid imaging device (e.g., a COMS image sensor).

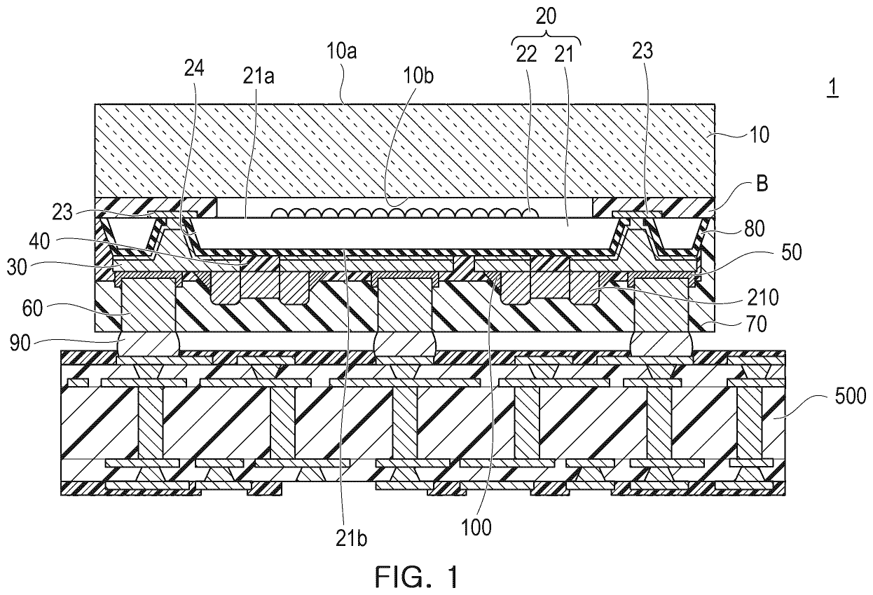

The semiconductor package 1 according to a first example embodiment may be described with reference to FIGS. 1 to 6.

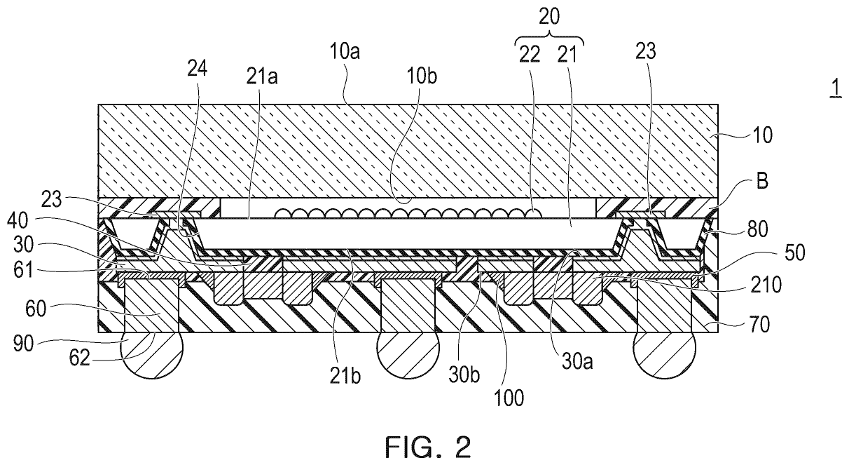

The semiconductor package 1 may include a transparent substrate 10, a first semiconductor chip 20, a first redistribution layer 30, a first insulating layer 40, a first conductive portion 50, a columnar electrode 60, an encapsulating resin layer 70, a second insulating layer 80, and a connection terminal 90 as illustrated in FIGS. 1 and 2. The semiconductor package 1 may be mounted on a mounting substrate 500 with a connection terminal 90 interposed therebetween as illustrated in FIG. 1.

Also, the semiconductor package 1 may have one or more first passive components 210. As illustrated in FIG. 2, the first passive components 210 (e.g., first surfaces of the first passive components 210 opposite to second surfaces of the first passive components 210 that are facing or in contact with the first redistribution layer 30) may be disposed at a lower position than the columnar electrode 60 (e.g., a first surface of the columnar electrode 60 opposite to a second surface of the columnar electrode 60 that is in contact with the first conductive portion 50) with respect to the second surface 30b of the first redistribution layer 30, and may be covered with the encapsulating resin layer 70. In other words, the height of each of the first passive components 210 may be less than the height of the columnar electrode 60.

The transparent substrate 10 may be formed of or include a transparent material having light transmittance, such as a glass material or a resin material (e.g., polyimide). A plane size of the transparent substrate 10 may be larger than a plane size of the chip substrate 21 of the first semiconductor chip 20. As illustrated in FIG. 2, the transparent substrate 10 may have a first surface 10a becoming an incident surface of light and a second surface 10b opposing the first surface 10a. The transparent substrate 10 may be bonded with a bonding portion B formed of or including an encapsulant material (or dam material) S interposed therebetween, while the second surface 10b and the first surface 21a of the chip substrate 21 of the first semiconductor chip 20 oppose each other. In FIG. 1, the first surface 10a of the transparent substrate 10 may be an upper surface of the transparent substrate 10, and the second surface 10b of the transparent substrate 10 may be a lower surface of the transparent substrate 10.

The first semiconductor chip 20 may have a chip substrate 21 formed of or including silicon or the like. The chip substrate 21 of the first semiconductor chip 20 may have a first surface 21a and a second surface 21b which is an opposite surface of the first surface 21a. An IC circuit may be formed on the first surface 21a. In FIG. 2, the first surface 21a of the chip substrate 21 may be an upper surface becoming an incident surface of light, and the second surface 21b of the chip substrate 21 may be a lower surface of the chip substrate 21.

The first semiconductor chip 20 may be configured as a CMOS image sensor including a plurality of pixels configured to convert incident light into an electric signal disposed in a matrix form, and including a color filter, a photodiode, a pixel circuit (not illustrated) mounted thereon in addition to an on-chip lens (or microlens) 22.

An electrode 23 may be formed on the first surface 21a of the chip substrate 21, and a through-hole (or via) 24 may be formed from the second surface 21 b to the electrode 23 so as to be electrically connected to the electrode 23. The through-hole 24 may be formed by a general etching process, such as deep reactive-ion etching (DRIE).

A second insulating layer 80 may be formed on the second surface 21b and a side surface of the chip substrate 21, and a side surface (e.g., a side boundary) of the through-hole 24. The second insulating layer 80 may be formed by a general thin film forming process such as a deposition method, a sputtering method, a CVD method, or the like, and at least a portion of the second insulating layer 80 formed on a surface opposing (e.g., facing) the electrode 23 that corresponds to a bottom portion of the through-hole 24 may be removed.

A first redistribution layer 30 may be formed by being stacked on the second insulating layer 80. The first redistribution layer 30 may have a first surface 30a on the first semiconductor chip 20 side, and a second surface 30b on an opposite surface to the first surface 30a.

The first redistribution layer 30 may be formed of or include a desired (or alternatively, predetermined) conductive pattern. The conductive pattern of the first redistribution layer 30 may be formed of or include metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or an alloy thereof. The first redistribution layer 30 may be formed by a general forming process. An electronic component such as a first passive component 210 may be mounted on the second surface 30b of the first redistribution layer 30.

A first insulating layer 40 may be formed by being stacked on and/or between the first redistribution layer 30. The first insulating layer 40 may be formed in an opening region other than a forming region of each conductive portion to electrically connect the first conductive portion 50, the second conductive portion 100, and the first redistribution layer 30 to each other. The first insulating layer 40 may be formed of or may include an insulating resin, such as a thermosetting resin (e.g., an epoxy resin) or a thermoplastic resin (e.g., a polyimide).

Further, a columnar electrode 60 may be stacked on the first conductive portion 50. The first conductive portion 50 may be interposed between the columnar electrode 60 and the first redistribution layer 30 and may electrically connect the columnar electrode 60 to the first redistribution layer 30. The first conductive portion 50 may be formed of or may include a conductive paste such as a conductive adhesive including copper particles, or a conductive material such as solder. The first conductive portion 50 may be formed by a general printing process such as a screen-printing method or an inkjet printing method.

An elastic modulus of the first conductive portion 50 may be lower than an elastic modulus of the columnar electrode 60. For example, the relationship between the elastic modulus of the first conductive portion 50 and the columnar electrode 60 may satisfy the relationship of “elastic modulus of the first conductive portion <elastic modulus of the columnar electrode.” The semiconductor package 1 may effectively reduce stress applied to the connection terminal 90 due to a difference in thermal expansions by forming the first conductive portion 50 having an elastic modulus lower than the elastic modulus of the columnar electrode 60 between the first redistribution layer 30 and the columnar electrode 60.

The columnar electrode 60 may be formed on the first conductive portion 50. The columnar electrode 60 may be an electrode member having a first end 61 connected to the first conductive portion 50, a second end 62 formed as a connection terminal 90, which is an end on an axially opposite side of the first end 61, and a side surface connecting the first end 61 to the second end 62, as illustrated in FIG. 2. The columnar electrode 60 may be formed as a metal pin having copper as a main component (e.g., a copper pin), and a member formed by a copper plating method such as electroplating or chemical plating in a pillar shape. In other words, the columnar electrode 60 may be formed of or include a metal pin or a plated metal. For example, when the columnar electrode 60 is formed as a metal pin, the member may be formed by simply disposing a metal pin functioning as an electrode in a forming position of the first conductive portion 50, thereby improving the assembling efficiency during manufacturing.

The encapsulating resin layer 70 may be formed to cover at least a side surface of the first conductive portion 50, a side surface of the columnar electrode 60, and the first passive component 210. The encapsulating resin layer 70 may be formed by filling an encapsulating resin into a space (or, an encapsulation space) becoming an encapsulating target of the semiconductor package 1. The encapsulating resin layer 70 may be formed to cover the first redistribution layer 30 and the first passive component 210 as illustrated in FIG. 2 and to expose the second end 62 of the columnar electrode 60. A connection terminal 90 may be formed on the second end 62 of the columnar electrode 60. The connection terminal 90 may be in physical contact with the second end 62 of the columnar electrode 60.

The encapsulating resin layer 70 may be formed as an insulating resin, such as an epoxy resin applied as a potting resin. The encapsulating resin layer 70 may include a non-conductive filler such as an inorganic filler having a spherical or a flat shape such as silica. A content of the non-conductive filler of the encapsulating resin layer 70 may be adjusted such that solder joint reliability of the semiconductor package 1 may improve. By adjusting the content of the filler, the encapsulating resin layer 70 may adjust the coefficient of linear expansion or elastic modulus of the encapsulating resin layer 70. Accordingly, the semiconductor package 1 may include the encapsulating resin layer 70 in which the content of the filler is adjusted, and accordingly, solder joint reliability may improve.

The encapsulating resin layer 70 may have a coefficient of linear expansion equal to or greater than that of the chip substrate 21 of the first semiconductor chip 20. The coefficient of linear expansion of the encapsulating resin layer 70 may be about 5 to about 15 ppm/° C., may be higher than the coefficient of linear expansion of the chip substrate 21 of the first semiconductor chip 20 (about 3 ppm/° C. or lower) and may have a value close to the coefficient of linear expansion of the mounting substrate 500 (15 to 20 ppm/° C.). The encapsulating resin layer 70 may be formed between the first semiconductor chip 20 and the mounting substrate 500 and may function as a stress alleviating layer which may significantly reduce stress applied to the connection terminal 90 due to temperature change occurring between the first semiconductor chip 20 and the mounting substrate 500.

The encapsulating resin layer 70 may have a light-shielding portion configured to block light of sensitivity wavelength of the image sensor, when the first semiconductor chip 20 is configured as an image sensor. The encapsulating resin layer 70 may include a light-shielding properties material, such as carbon or a filler, such that light-shielding properties may be obtained, and the entire layer may function as a light-shielding portion. The encapsulating resin layer 70 may form a film or layer having light-shielding properties thereon and cover a portion or the entirety of the encapsulating resin layer 70 as the light-shielding portion. The semiconductor package 1 including the image sensor may reduce adverse effects on the sensor due to stray light, such as reflected light or scattered light as the encapsulating resin layer 70 forms on includes the light-shielding portion.

The connection terminal 90 may be formed of or include a conductive material such as solder and may be connected to the second end 62 of the columnar electrode 60. In the semiconductor package 1, the connection terminal 90 may not be formed at the second end 62 of the columnar electrode 60.

The first passive component 210 may be formed as a passive component such as a power capacitor or a matching element. The first passive component 210 may be disposed on the second surface 30b of the first redistribution layer 30. Accordingly, the first passive component 210 may be mounted in the semiconductor package 1. The first passive component 210 (e.g., a first surface of the first passive component 210 opposite to a second surface of the first passive component 210 that is facing or in contact with the first redistribution layer 30) may be disposed at a position lower than the columnar electrode 60 (e.g., a first surface of the columnar electrode 60 opposite to a second surface of the columnar electrode 60 that is facing or in contact with the first conductive portion 50) with respect to the second surface 30b of the first redistribution layer 30 and may be covered with an encapsulating resin layer 70. In other words, the height of each of the first passive components 210 may be less than a height of the columnar electrode 60 and the encapsulating resin layer 70 may cover the first passive components 210 and surround the columnar electrode 60. The first passive component 210 may be disposed on the second conductive portion 100 formed on the second surface 30b of the first redistribution layer 30. The second conductive portion 100 may be formed of or include a conductive paste such as a conductive adhesive including copper particles or a conductive material such as a solder, similarly to the first conductive portion 50.

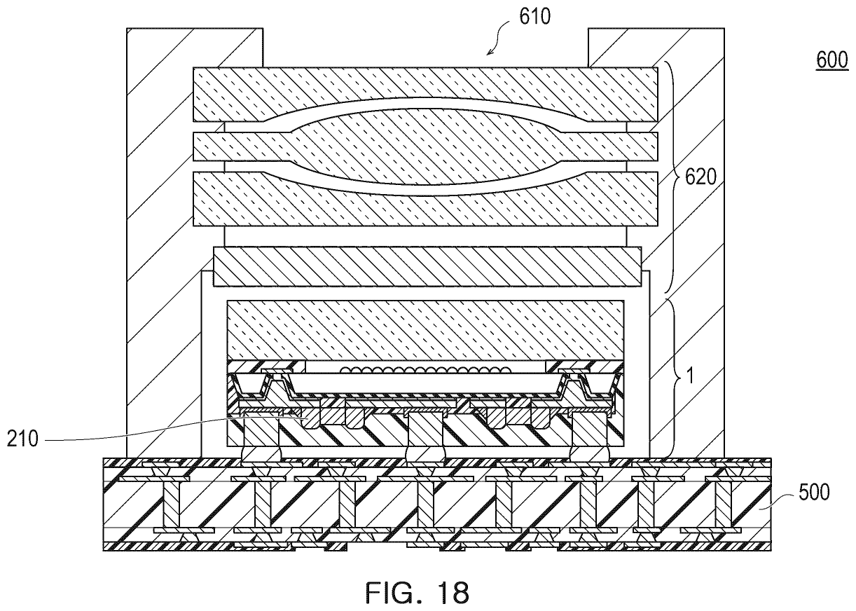

When the semiconductor package 1 is mounted on, for example, a camera module 600 as illustrated in FIG. 18, the passive component which may be mounted in the camera module 600 may be mounted as the first passive component 210 in the semiconductor package 1. Accordingly, the camera module 600 may obtain good electrical properties by reducing the module size and shortening the distance between the semiconductor package 1 and the first passive component 210.

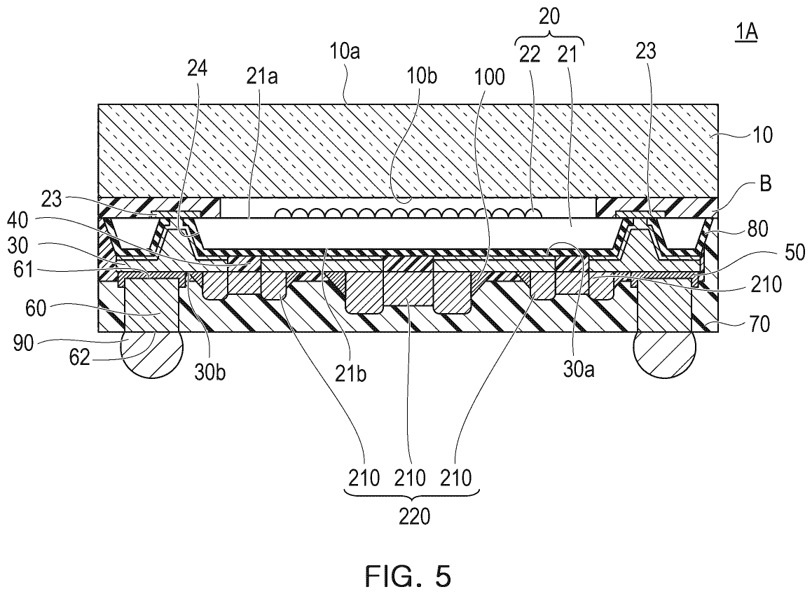

The first passive component 210 may be included in a first passive component group 220 configured as a plurality of passive components as illustrated in FIG. 5, for example. The first passive component group 220 may include components having approximately uniform levels or may include components having different levels. The first passive component group 220 may include components having different functions.

In the description below, a method of manufacturing a semiconductor package 1 may be described.

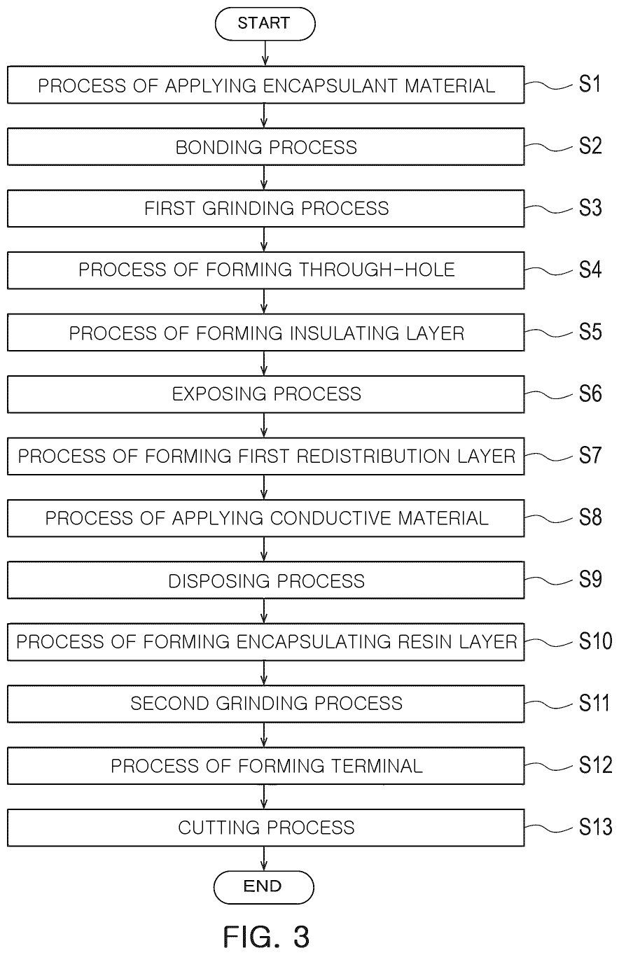

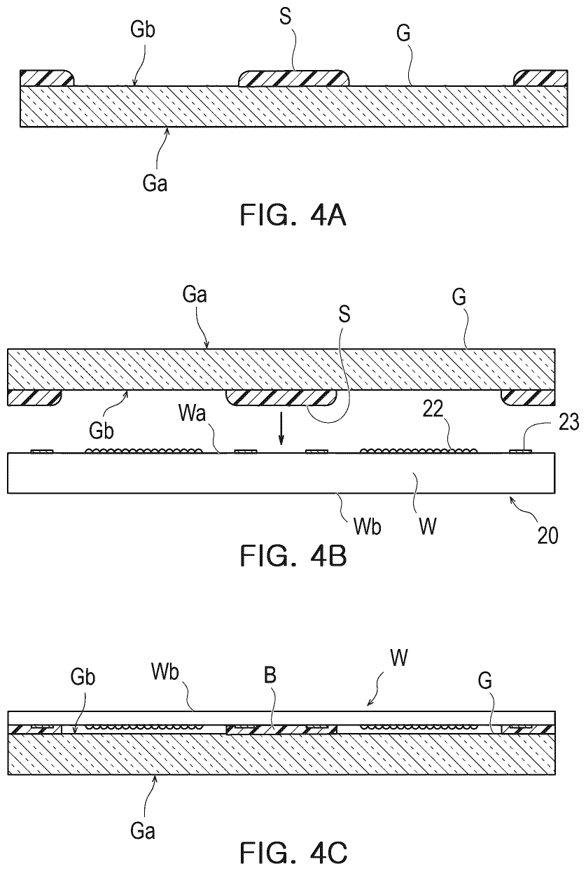

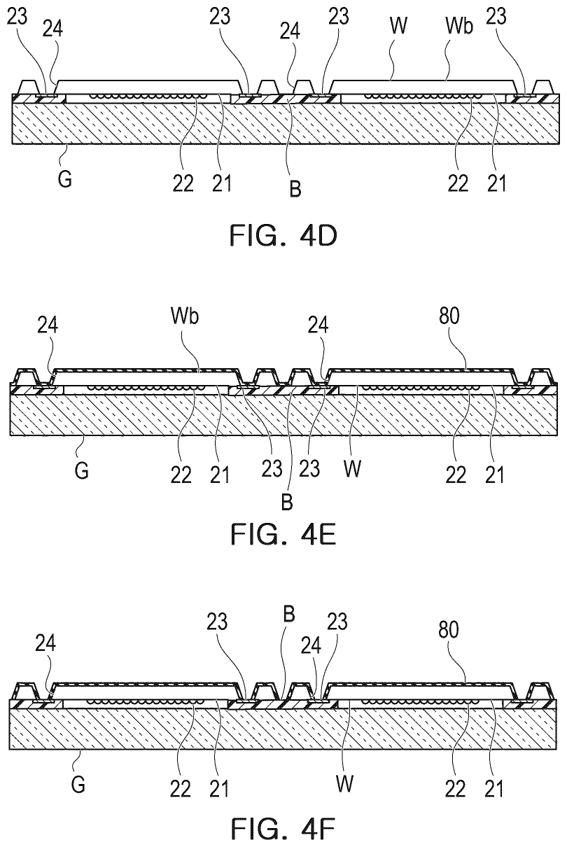

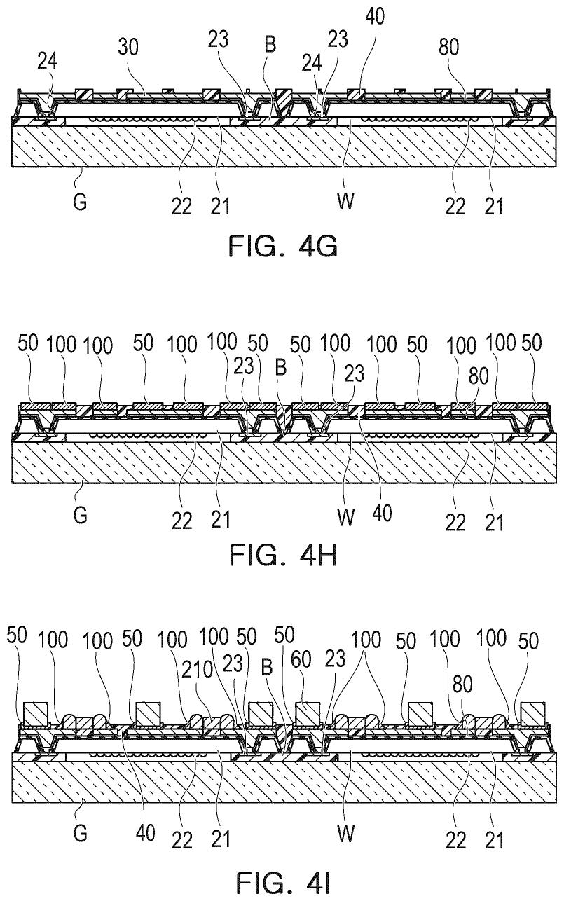

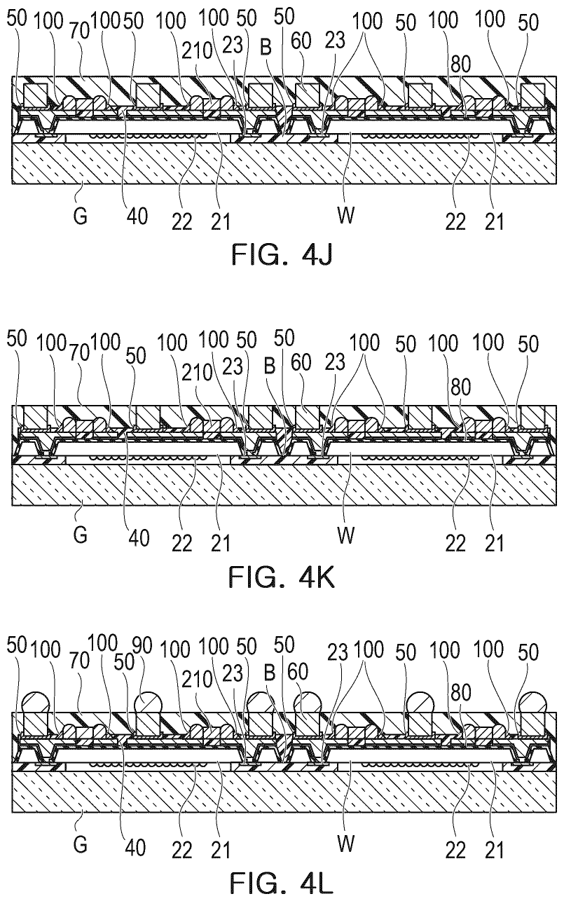

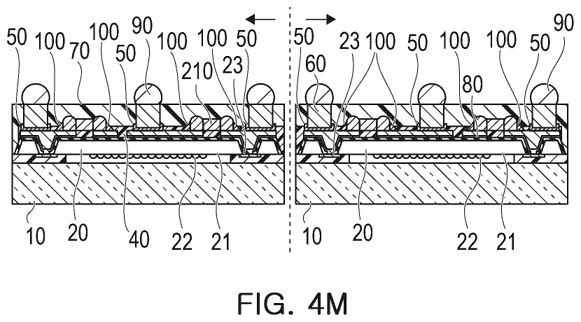

As illustrated in FIG. 3, a method of manufacturing a semiconductor package 1 may include a process of applying an encapsulant material (S1) as process 1, a boning process (S2) as process 2, a first grinding process (S3) as process 3, a process of forming a through-hole (S4) as process 4, a process of forming an insulating layer (S5) as process 5, an exposing process (S6) as process 6, a process of forming a first redistribution layer (S7) as process 7, a process of applying a conductive material (S8) as process 8, a disposing process (S9) as process 9, a process of forming an encapsulating resin layer (S10) as process 10, a second grinding process (S11) as process 11, a process of forming a terminal (S12) as process 12, and a cutting process (S13) as process 13. FIGS. 4A to 4M are diagrams illustrating each process (process 1 to process 13) included in the method of manufacturing the semiconductor package 1.

Process 1 may include a process of applying an encapsulant material S (S1) functioning as a bonding portion B to a second surface Gb of a glass substrate G that will become a transparent substrate 10 and a first surface Ga opposing thereto as illustrated in FIG. 4A. The encapsulant material S may be applied to include a periphery of each of the packages and a separated boundary portion.

Process 2 may include a bonding process (S2) of bonding the second surface Gb of the glass substrate G applied with the encapsulant material S, and the first surface Wa of the semiconductor wafer W that will become the chip substrate 21 of the first semiconductor chip 20 to oppose each other as illustrated in FIG. 4B. The semiconductor wafer W may include components (e.g., on-chip lens 22, an electrode 23, and other image sensors) mounted on the light-receiving region of each of the packages of the first surface Wa. In process 2, a bonding portion B may be formed by performing a curing process on the encapsulant material S.

Process 3 may include a first grinding process (S3) of back-grinding the second surface Wb of the semiconductor wafer W to a thickness of a desired (or alternatively, predetermined) chip size as illustrated in FIG. 4C.

Process 4 may include a process of forming a through-hole (S4) for forming a through-hole 24 by etching from the second surface Wb of the semiconductor wafer W as illustrated in FIG. 4D. The through-hole 24 may be formed by a deep reactive-ion etching (DRIE) process. The through-hole 24 may be formed in a forming position of the electrode 23 or a boundary position of the package. By forming the through-hole 24, a portion of electrode 23 and a portion of the bonding portion of the boundary portion B may be exposed.

Process 5 may include a process of forming an insulating layer (S5) of forming a second insulating layer 80 on the entire second surface Wb of the semiconductor wafer W as illustrated in FIG. 4E. The process of forming the second insulating layer 80 may be performed by a deposition method, a sputtering method, a CVD method, or the like.

Process 6 may include an exposing process (S6) of removing the second insulating layer 80 positioned on the bottom portion of the through-hole 24 to expose a portion of the electrode 23, for electrical connection with another layer to be placed thereon later, as illustrated in FIG. 4F. The removing process of the second insulating layer 80 may be performed by an etching process, or the like.

Process 7 may include a process of forming a first redistribution layer (S7) for forming a first redistribution layer 30 on the second insulating layer 80 as illustrated in FIG. 4G. The first redistribution layer 30 may be formed to be electrically connected to the electrode 23 using a photolithography method and a plating method. Also, in process 7, because the first conductive portion 50, the second conductive portion 100, and the first redistribution layer 30, formed in the subsequent process, are electrically connected, the first insulating layer 40 may be formed in an opening region other than the forming region of each conductive portion in advance. Also, in process 7, the first insulating layer 40 may be formed, and a process of removing the first insulating layer 40 corresponding to the forming region of each conductive portion may be performed.

Process 8 may include a process of applying a conductive material (S8) for forming the first conductive portion 50 and the second conductive portion 100 by applying a conductive paste as a conductive material as illustrated in FIG. 4H. The first conductive portion 50 may be formed on the first redistribution layer 30 corresponding to the arrangement position of the columnar electrode 60. The second conductive portion 100 may be formed on the first redistribution layer 30 corresponding to the arrangement position of the first passive component 210. The process of forming the first conductive portion 50 and the second conductive portion 100 may be performed by a screen-printing method or an inkjet printing method in a state in which a mask is disposed of in a region other than the forming position. In process 8, the conductive material may be a conductive paste, but solder may be used. In some example embodiments, different materials may be used for the first conductive portion 50 and the second conductive portion 100.

Process 9 may include a disposing process (S9) for disposing the columnar electrode 60 and the first passive component 210 as illustrated in FIG. 4I. The arrangement of the columnar electrode 60 may be similar to the ball-mounting method, and may be performed by a process of disposing a mask in a region other than the first conductive portion 50 such that the first conductive portion 50 illustrated in FIG. 4H is exposed, a process of returning a plurality of metal pins (e.g., copper pins) that will become the columnar electrode 60 on the mask, disposing and allowing the metal pins (e.g., copper pins) from the opening portion of the mask to be in contact with each of the first conductive portions 50, and a process of removing the mask and drying, sintering, and curing the first conductive portion 50. The end of the columnar electrode 60 in contact with the first conductive portion 50 may be the first end 61. The first passive component 210 may be mounted on the first redistribution layer 30 by a general mounting process (e.g., a mounting process by a mounting device, or the like). Also, process 9may also include a process of reflowing the conductive material. By the reflow process, the columnar electrode 60 and the first passive component 210 may be fixed to the first redistribution layer 30.

In process 9, the columnar electrode 60 and the first passive component 210 may be mounted in the same process, but example embodiments thereof are not limited thereto, and the columnar electrode 60 and the first passive component 210 may be mounted in different processes, respectively. Also, as for the process of reflowing the conductive material, a process different from process 9 may be performed.

Process 10 may include a process of forming an encapsulating resin layer (S10) for forming an encapsulating resin layer 70 as illustrated in FIG. 4J. The encapsulating resin layer 70 may be formed by filling an encapsulation space with a resin including a non-conductive filler, such as an epoxy resin. Also, the encapsulating resin layer 70 may be applied so as to cover the first passive component 210. Accordingly, the encapsulating resin layer 70 may be formed so as to cover a side surface of the first conductive portion 50, a side surface of the columnar electrode 60, the first redistribution layer 30, and the first passive component 210 in a state in which the second end 62 of the columnar electrode 60 is exposed.

Process 11 may include a second grinding process (S11) for exposing the second end 62 of the columnar electrode 60 by back-grinding the encapsulating resin layer 70 as illustrated in FIG. 4K.

Process 12 may include a process of forming a terminal (S12) for forming a connection terminal 90 on the second end 62 of the columnar electrode 60 as illustrated in FIG. 4L. The process of forming the connection terminal 90 may be performed by a ball mounting method, a screen-printing method, or the like. For example, in process 12, the level positions of the contact surfaces of the connection terminals 90 for the mounting substrate (500 in FIG. 1) may be formed to be almost the same position in the thickness direction of the semiconductor package 1 from the viewpoint of ease of mounting.

Process 13 may include a cutting process (S13) for cutting a desired (or alternatively, predetermined) region of a semiconductor wafer W and singulating a semiconductor package 1 as illustrated in FIG. 4M. Through the above process, the semiconductor package 1 illustrated in FIG. 2 may be manufactured.

The method of manufacturing a semiconductor package 1 described above may include a process of performing another process other than process 1 to process 13 (e.g., a process of performing a cleaning process, or the like) if desired. Also, in the method of manufacturing a semiconductor package 1, the order of performing the processes may be appropriately modified and performed within a range in which the configuration and function of the manufactured semiconductor package 1 do not deviate from the gist of the present disclosure.

Also, in the manufacturing method described above, in the semiconductor package 1, a connection terminal 90 may not be formed at the second end 62 of the columnar electrode 60. In this case, process 12 may not be performed.

According to some modified example embodiments of the first example embodiment, the semiconductor package 1 may be configured as described below.

FIG. 5 illustrates a semiconductor package 1a, which is a modified example of the first example embodiment. In the semiconductor package 1a, first passive components 210 having different levels may be mounted as illustrated in FIG. 5. In the semiconductor package 1a, the first passive component 210 (e.g., a first surface of the first passive component 210 opposite to a second surface of the first passive component 210 that is facing or in contact with the first redistribution layer 30) having a relatively low level with respect to the second surface 30b of the first redistribution layer 30 may be disposed on the outer circumferential side (e.g., an outer circumferential portion) of the first semiconductor chip 20 in a cross-section. In other words, when the first passive components 210 include one passive component having a first height and another passive component having a second height greater than the first height, the one passive component may be disposed on an outer circumferential portion of the first semiconductor chip 20. Also, in the semiconductor package 1a, the first passive component 210 (e.g., a first surface of the first passive component 210 opposite to a second surface of first passive component 210 that is facing or in contact with the first redistribution layer 30) having a relatively high level with respect to the second surface 30b of the first redistribution layer 30 may be disposed on the central side (e.g., a central portion) of the first semiconductor chip 20 in a cross-section. In other words, a first passive component 210 having a relatively small height may be disposed on the outer circumferential side (e.g., an outer circumferential portion) of the first semiconductor chip 20 in a cross-section, and another first passive component 210 having a relatively large height may be disposed on the central side (e.g., a central portion) of the first semiconductor chip 20 in a cross-section.

By arranging the first passive component 210 as illustrated in FIG. 5, the semiconductor package 1a may reduce or prevent the flow of the encapsulating resin filled in the encapsulation space from being impeded by the first passive component 210 having a relatively high level when forming the encapsulating resin layer 70. Accordingly, the semiconductor package 1a may reduce voids, or the like, after the encapsulating resin layer 70 is formed.

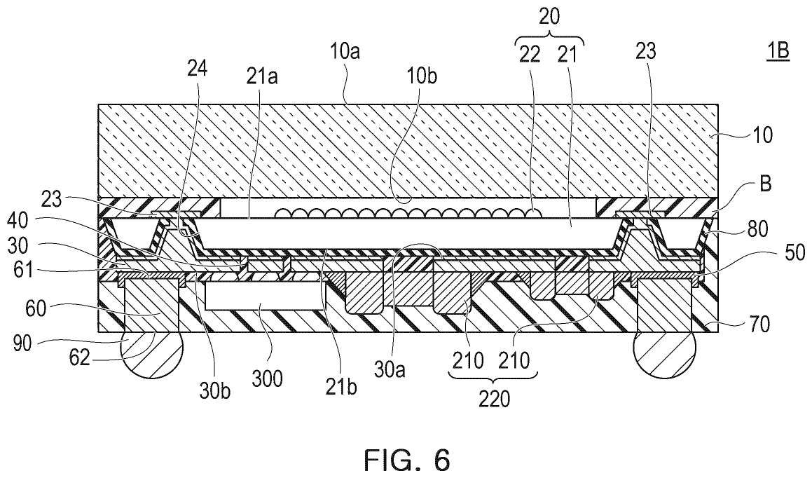

FIG. 6 illustrates a semiconductor package 1b, which is another modified example of the first example embodiment. In the semiconductor package 1b, the first passive component 210 and the second semiconductor chip 300 may be mounted on the second surface 30b of the first redistribution layer 30 as illustrated in FIG. 6. In the semiconductor package 1b, other electronic components, such as a second semiconductor chip 300 may be mounted on the second surface 30b of the first redistribution layer 30 in addition to one or more first passive components 210. With this configuration, the semiconductor package 1b may become more highly functional.

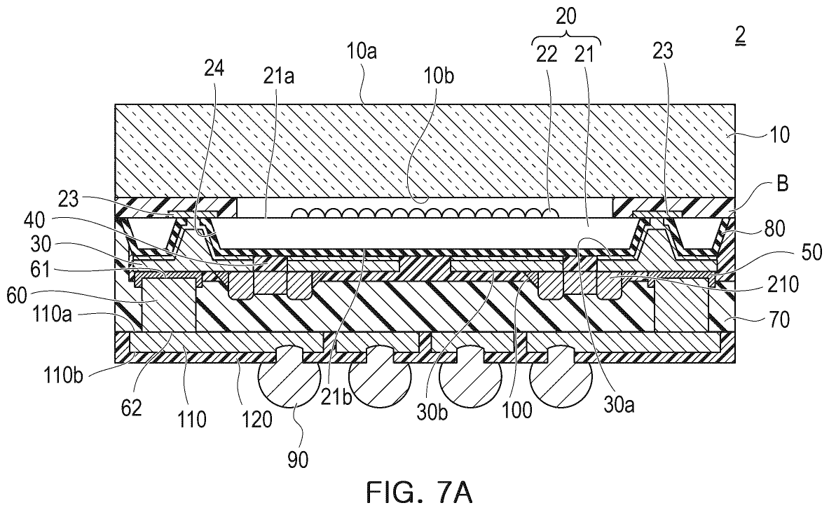

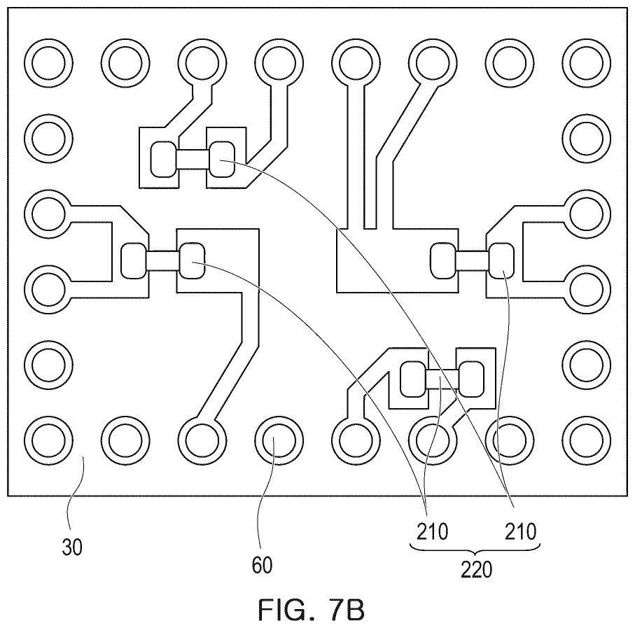

The semiconductor package 2 according to a second example embodiment may be described with reference to FIGS. 7A to 11. The semiconductor package 2 may be assigned the same reference numerals as the above-described example embodiments and the description thereof may not be provided. Also, unless otherwise indicated, the second example embodiment may be configured in the same manner as the above-described example embodiments.

The semiconductor package 2 may include a transparent substrate 10, a first semiconductor chip 20, a first redistribution layer 30, a first insulating layer 40, a first conductive portion 50, a columnar electrode 60, an encapsulating resin layer 70, a second insulating layer 80, a connection terminal 90, and a second redistribution layer 110 as illustrated in FIG. 7A. The semiconductor package 2 may be mounted on a mounting substrate (500 in FIG. 1) by interposing the connection terminal 90. The semiconductor package 2 may be different from the semiconductor package 1 of the first example embodiment in that the semiconductor package 2 may have a second redistribution layer 110 stacked on the encapsulating resin layer 70.

The second redistribution layer 110 may be formed by stacking on the encapsulating resin layer 70. The second redistribution layer 110 may be connected to the second end 62 of the columnar electrode 60.

The second redistribution layer 110 may be formed with a desired (or alternatively, predetermined) conductive pattern. The conductive pattern of the second redistribution layer 110 may be formed with or include the same material as the first redistribution layer 30. The process of forming the second redistribution layer 110 may be performed by a general forming process. The second redistribution layer 110 may have a first surface 110a on the first semiconductor chip 20 and a second surface 110b which is an opposite surface of the first surface 110a.

The second redistribution layer 110 may be formed by stacking a third insulating layer 120. The third insulating layer 120 may be formed such that a portion of the second redistribution layer 110 at the forming region of the connection terminal 90 may be exposed. The third insulating layer 120 may be formed of or include the same insulating resin as the first insulating layer 40.

A connection terminal 90 may be disposed on the second surface 110b of the second redistribution layer 110. The connection terminal 90 may be electrically connected to the first passive component 210 or the first semiconductor chip 20 through the columnar electrode 60 and the second redistribution layer 110.

In the semiconductor package 1 of the first example embodiment, the arrangement of the columnar electrode 60 may be determined depending on the arrangement of the first passive component 210 to be mounted. Also, in the semiconductor package 1, a diameter of the columnar electrode 60 may vary according to the size of the connection terminal 90. As described above, in the semiconductor package 1, the arrangement or size of the columnar electrode 60 may be limited.

Differently from the semiconductor package 1 of the first example embodiment, in the semiconductor package 2 of the second example embodiment, the columnar electrode 60 may be disposed in the empty space of the first redistribution layer 30 (e.g., the outer circumferential side/portion of the second surface 30b of the first redistribution layer 30) as illustrated in FIG. 7B. Accordingly, in the semiconductor package 2, the connection terminal 90 may be disposed regardless of the arrangement of the first passive component 210 to be mounted. Also, as for the semiconductor package 2, the size of the connection terminal 90 may not need to be considered. Thus, the size of the columnar electrode 60 may be reduced. Also, in the semiconductor package 2, it may not be desired to form the connection terminal 90 at the second end 62 of the columnar electrode 60. Accordingly, in the semiconductor package 2, the arrangement of connection terminal 90 formed on the second surface 110b of the second redistribution layer 110 may be disposed in at a desired position. Also, in the semiconductor package 2, an encapsulating resin layer 70 functioning as a stress alleviating layer may be formed to cover a portion of the first redistribution layer 30 and the columnar electrode 60, similarly to the semiconductor package 1 of the first example embodiment. Accordingly, the semiconductor package 2 may be a package in which solder stress due to temperature change during package mounting is greatly reduced and solder joint reliability during package mounting is improved.

In the description below, a method of manufacturing the semiconductor package 2 may be described.

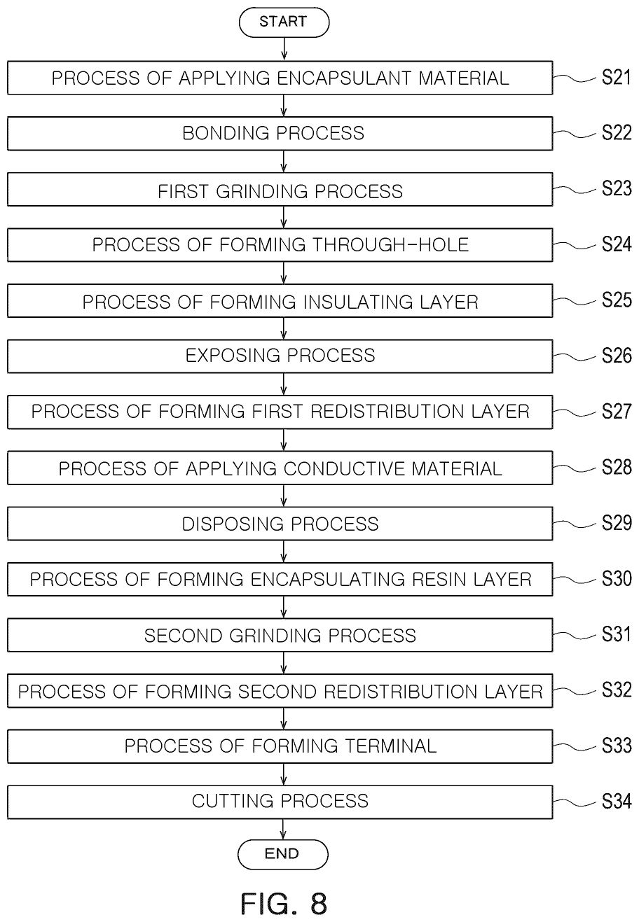

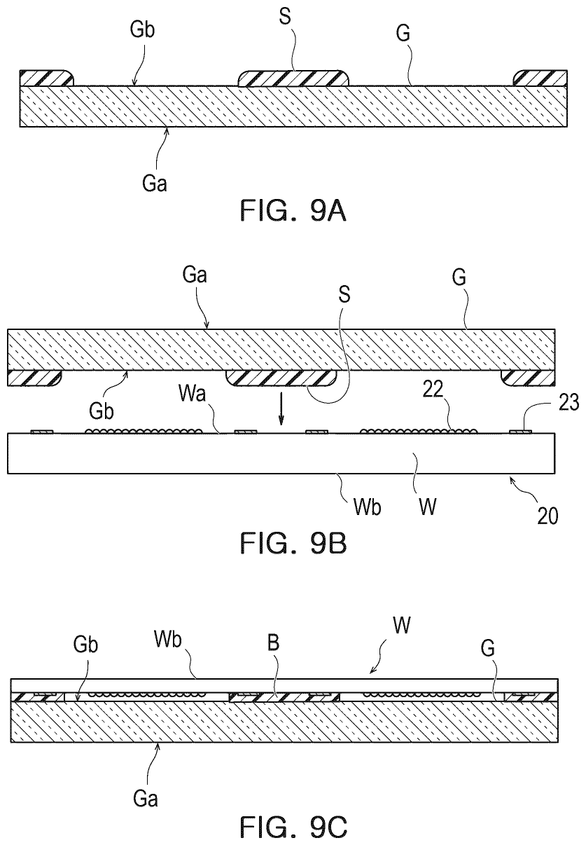

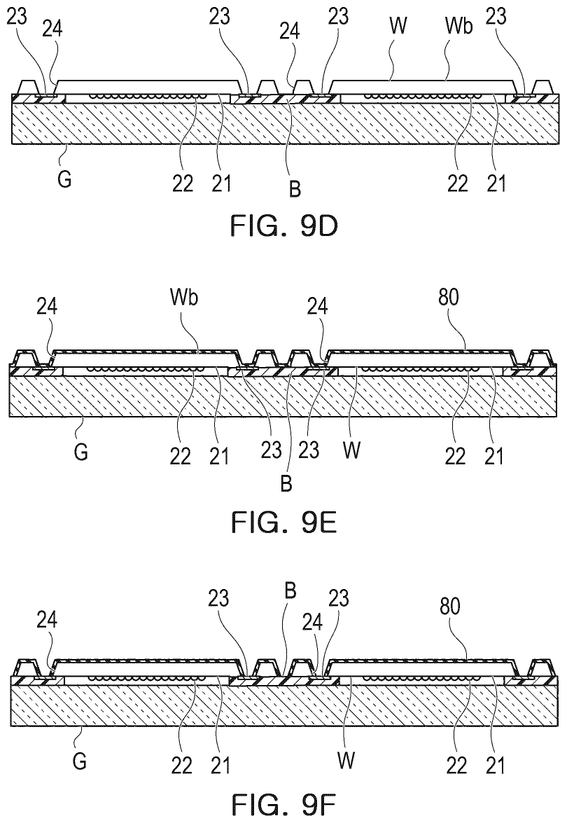

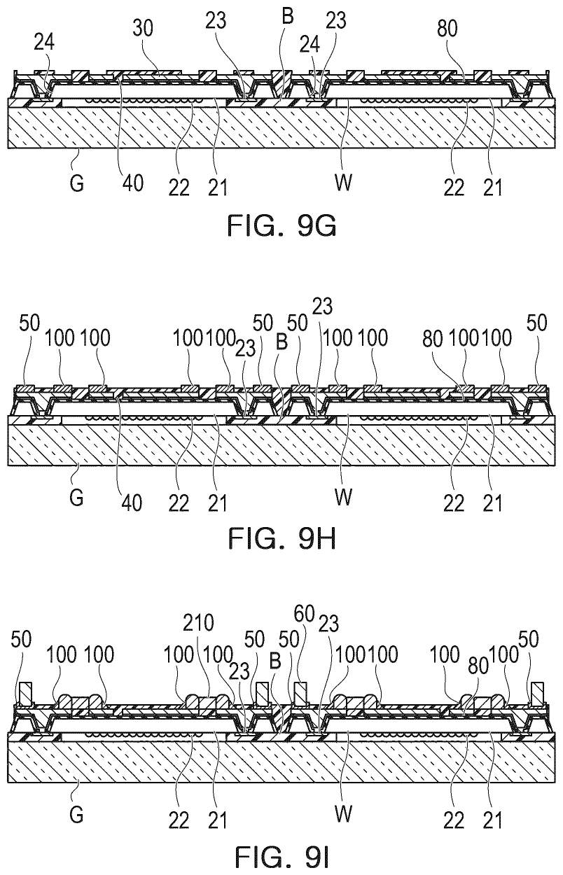

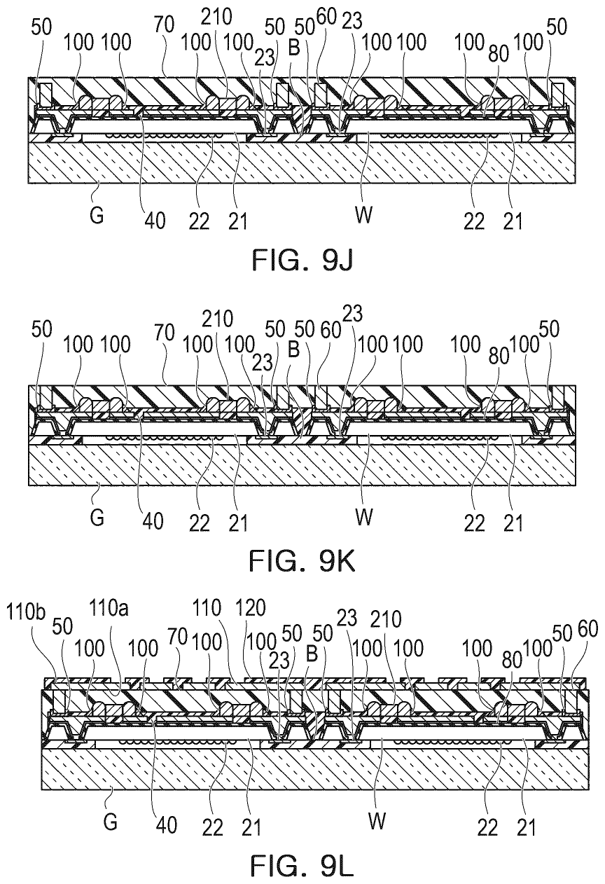

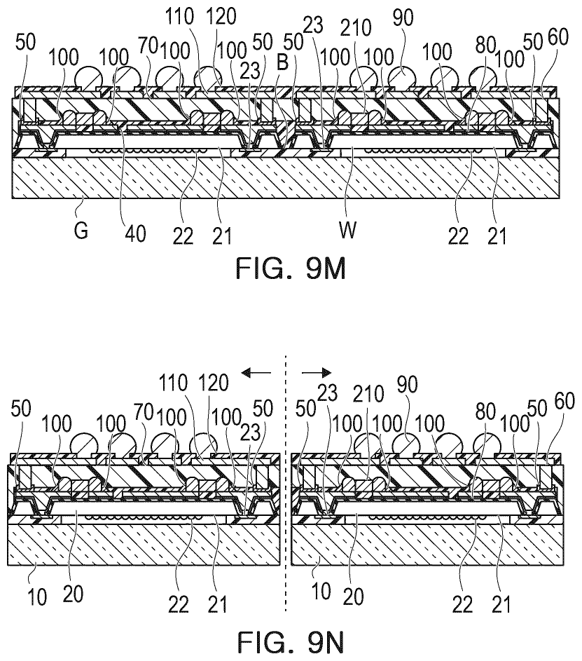

As illustrated in FIG. 8, the method of manufacturing a semiconductor package 2 may include a process of applying an encapsulant material (S21) as process 1, a boning process (S22) as process 2, a first grinding process (S23) as process 3, a process of forming a through-hole (S24) as process 4, a process of forming an insulating layer (S25) as process 5, an exposing process (S26) as process 6, a process of forming a first redistribution layer (S27) as process 7, a process of applying a conductive material (S28) as process 8, a disposing process (S29) as process 9, a process of forming an encapsulating resin layer (S30) as process 10, a second grinding process (S31) as process 11, a process of forming a second redistribution layer (S32) as process 12, a process of forming a terminal (S33) as process 13, and a cutting process (S34) as process 14. FIGS. 9A to 9N are diagrams illustrating each process (process 1 to process 14) included in the method of manufacturing the semiconductor package 2.

Process 1 may perform a process of applying an encapsulant material (S21) for applying an encapsulant material S functioning as a bonding portion B to a second surface Gb opposing a first surface Ga of a glass substrate G that will become a transparent substrate 10 as illustrated in FIG. 9A. The encapsulant material S may be applied to include a periphery of each of the packages and a separated boundary portion.

Process 2 may include a bonding process (S22) for bonding the second surface Gb of the glass substrate G applied with the encapsulant material S, and the first surface Wa of the semiconductor wafer W that will become the chip substrate 21 of the first semiconductor chip 20 to oppose each other as illustrated in FIG. 9B. The semiconductor wafer W may include components (e.g., on-chip lens 22, electrode 23, and other image sensors) mounted on the light-receiving region of each package of the first surface Wa. In process 2, a curing process may be performed on the encapsulant material S and a bonding portion B may be formed.

Process 3 may include a first grinding process (S23) of back-grinding the second surface Wb of the semiconductor wafer W to a thickness of a desired (or alternatively, predetermined) chip size as illustrated in FIG. 9C.

Process 4 may include a process of forming a through-hole (S24) of forming a through-hole 24 by etching from the second surface Wb of the semiconductor wafer W as illustrated in FIG. 9D. The through-hole 24 may be formed by a deep reactive-ion etching (DRIE) process. The through-hole 24 may be formed in a forming position of the electrode 23 or a boundary position of the package. By forming the through-hole 24, a portion of the electrode 23 and a portion of the bonding portion B of the boundary portion may be exposed.

Process 5 may include a process of forming an insulating layer (S25) for forming a second insulating layer 80 on the entire surface of the second surface Wb of the semiconductor wafer W as illustrated in FIG. 9E. The process of forming the second insulating layer 80 may be performed by a deposition method, a sputtering method, a CVD method, or the like.

Process 6 may include an exposing process (S26) for removing the second insulating layer 80 positioned at the bottom portion of the through-hole 24 to expose a portion of the electrode 23, for electrical connection with another layer to be placed thereon later, as illustrated in FIG. 9F. The removing process of the second insulating layer 80 may be performed by an etching process, or the like.

Process 7 may include a process of forming a first redistribution layer (S27) for forming a first redistribution layer 30 on a second insulating layer 80 as illustrated in FIG. 9G. The first redistribution layer 30 may be formed to be electrically connected to the electrode 23 using a photolithography method and a plating method. Also, in process 7, the first conductive portion 50 and the second conductive portion 100 formed in the subsequent process may be electrically connected to the first redistribution layer 30, such that the first insulating layer 40 may be formed in an opening region other than the forming region of each conductive portion in advance.

Process 8 may include a process of applying a conductive material (S28) for forming a first conductive portion 50 and a second conductive portion 100 by applying a conductive paste as a conductive material as illustrated in FIG. 9H. The first conductive portion 50 may be formed on the first redistribution layer 30 corresponding to the arrangement position of the columnar electrode 60. The second conductive portion 100 may be formed on the first redistribution layer 30 corresponding to the arrangement position of the first passive component 210. The process of forming the first conductive portion 50 and the second conductive portion 100 may be performed by a screen-printing method or an inkjet printing method, or the like, while a mask is disposed in a region other than the forming position. In process 8, the conductive material may be a conductive paste, or solder may be used. In some example embodiments, different materials may be used for the first conductive portion 50 and the second conductive portion 100.

Process 9 may include a disposing process (S29) for disposing the columnar electrode 60 and the first passive component 210 as illustrated in FIG. 9I. The arrangement of the columnar electrode 60 may be similar to the ball-mounting method, and may be performed by a process of disposing a mask in a region other than the first conductive portion 50 such that the first conductive portion 50 illustrated in FIG. 9H may be exposed, a process of returning a plurality of metal pins (e.g., copper pins) that will become the columnar electrode 60 on the mask while disposing and allowing the metal pins (e.g., copper pins) to be in contact with each of the first conductive portions 50 from the opening portion of the mask, and a process for removing the mask and drying, sintering, and curing the first conductive portion 50. The end of the columnar electrode 60 in contact with the first conductive portion 50 may be the first end 61. The first passive component 210 may be mounted on the first redistribution layer 30 by a general mounting process (e.g., a mounting process by a mounting device, or the like). Also, the process 9 may also include a process of reflowing the conductive material. By the reflow process, the columnar electrode 60 and the first passive component 210 may be fixed to the first redistribution layer 30.

In the process 9, the columnar electrode 60 and the first passive component 210 may be mounted in the same process, but example embodiments thereof are not limited thereto, and the columnar electrode 60 and the first passive component 210 may be mounted in different processes, respectively. Also, as for the process of reflowing the conductive material, a process different from the process 9 may be performed.

Process 10 may include a process of forming an encapsulating resin layer (S30) for forming an encapsulating resin layer 70 as illustrated in FIG. 9J. The encapsulating resin layer 70 may be formed by filling an encapsulation space with an encapsulating resin including a non-conductive filler, such as an epoxy resin. Also, the encapsulating resin layer 70 may be applied so as to cover the first passive component 210. Accordingly, the encapsulating resin layer 70 may be formed so as to cover the first conductive portion 50, a side surface of the columnar electrode 60, the first redistribution layer 30, and the first passive component 210, while the second end 62 of the columnar electrode 60 is exposed.

Process 11 may include a second grinding process (S31) for exposing the second end 62 of the columnar electrode 60 by back-grinding the encapsulating resin layer 70 as illustrated in FIG. 9K. Accordingly, the second end 62 of the columnar electrode 60 may be exposed from the encapsulating resin layer 70.

Process 12 may include a process of forming a second redistribution layer (S32) for forming a second redistribution layer 110 on the encapsulating resin layer 70 as illustrated in FIG. 9L. The second redistribution layer 110 may be formed to be electrically connected to the second end 62 of the columnar electrode 60 using photolithography and plating, similarly to the process of forming a first redistribution layer (S27). Also, the second redistribution layer 110 may be formed to be electrically connected to the second end 62 of the columnar electrode 60. Also, the third insulating layer 120 may be formed to expose the second redistribution layer 110 of the formation region of the connection terminal 90.

Process 13 may include a process of forming a terminal (S33) for forming a connection terminal 90 at the second end 62 of the columnar electrode 60 as illustrated in FIG. 9M. The process of forming the connection terminal 90 may be performed by a ball mounting method, a screen-printing method, or the like. In process 12, the level positions of the contact surfaces of the connection terminals 90 for the mounting substrate (500 in FIG. 1) may be formed to be almost the same position in the thickness direction of the semiconductor package 2 from the viewpoint of ease of mounting.

Process 14 may include a cutting process (S34) for cutting a desired (or alternatively, predetermined) region of a semiconductor wafer W and singulating a semiconductor package 2 as illustrated in FIG. 9N. Through the above process, the semiconductor package 2 illustrated in FIG. 7A may be manufactured.

The method of manufacturing a semiconductor package 2 described above may include a process for performing processes other than processes 1 to 14 (e.g., a process for performing a cleaning process, or the like) if desired. Also, in the method of manufacturing a semiconductor package 2, the order of performing processes may be appropriately modified and performed within a range in which the configuration and function of the semiconductor package 2 to be manufactured do not deviate from the gist of the present disclosure.

Also, in the method of manufacturing a semiconductor package 2 described above, the connection terminal 90 may not be formed at the second end 62 of the columnar electrode 60. In this case, process 13 may not be performed.

According to some modified example embodiments of the second example embodiment, the semiconductor package 2 may be configured as below.

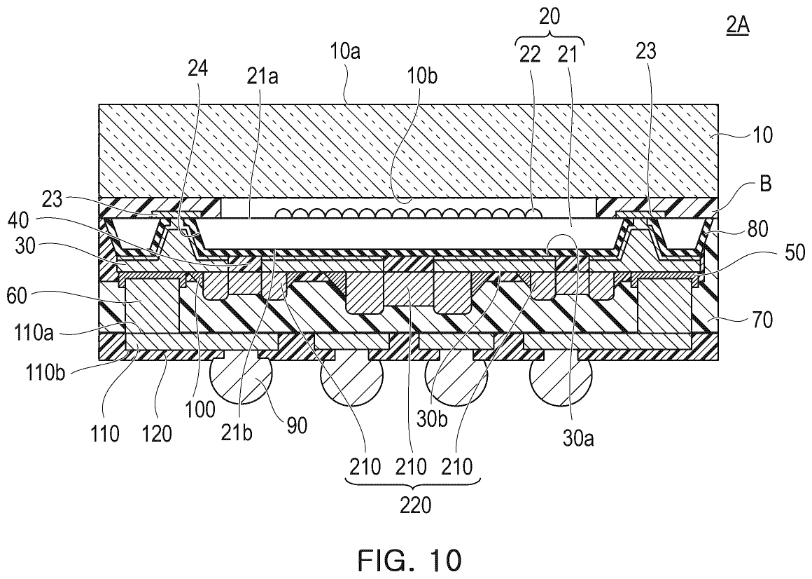

FIG. 10 illustrates a semiconductor package 2A, which is a modified example of the second example embodiment. In the semiconductor package 2A, a first passive component 210 having a different level may be mounted in the encapsulation space between the first redistribution layer 30 and the second redistribution layer 110 as illustrated in FIG. 10. In the semiconductor package 2A, a first passive component 210 (e.g., a first surface of the first passive component 210 opposite to a second surface of the first passive component 210 that is facing or in contact with the first redistribution layer 30) having a relatively low level with respect to the second surface 30b of the first redistribution layer 30 may be disposed on the outer circumferential side (e.g., an outer circumferential portion) of the first semiconductor chip 20 in a cross-section. Also, in the semiconductor package 2A, a first passive component 210 (e.g., a first surface of the first passive component 210 opposite to a second surface of first passive component 210 that is facing or in contact with the first redistribution layer 30) having a relatively high level with respect to the second surface 30b of the first redistribution layer 30 may be disposed on the central portion of the first semiconductor chip 20 in a cross-section.

In the semiconductor package 2A, by disposing the first passive component 210 as illustrated in FIG. 10, the flow of the encapsulating resin filled in the encapsulation space may be reduced or prevented from being impeded by the first passive component 210 having a relatively high level when the encapsulating resin layer 70 is formed. Accordingly, in the semiconductor package 2A, voids may be reduced after the encapsulating resin layer 70 is formed.

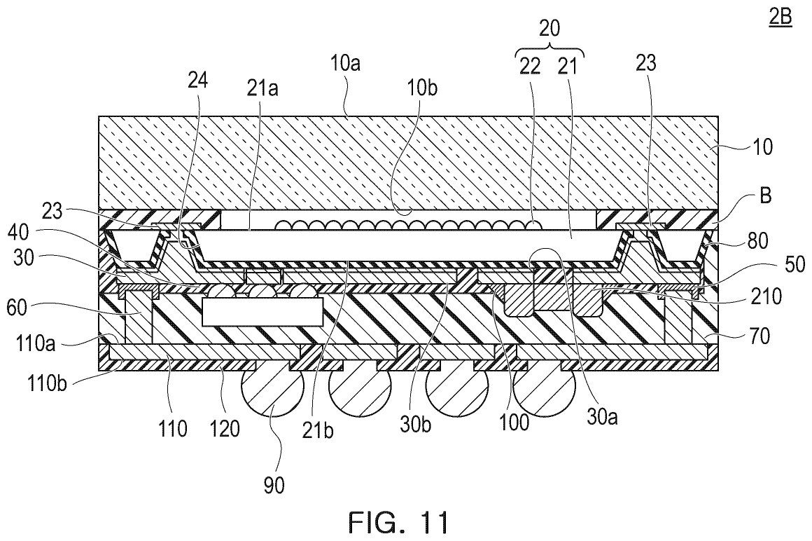

FIG. 11 illustrates a semiconductor package 2B, which is another modified example of the second example embodiment. In the semiconductor package 2B, a first passive component 210 and a second semiconductor chip 300 may be mounted on a second surface 30b of a first redistribution layer 30 as illustrated in FIG. 11. In the semiconductor package 2B, other electronic components, such as a second semiconductor chip 300, may be mounted on the second surface 30b of the first redistribution layer 30 in addition to one or more first passive components 210. With this configuration, semiconductor package 2B may become highly functional.

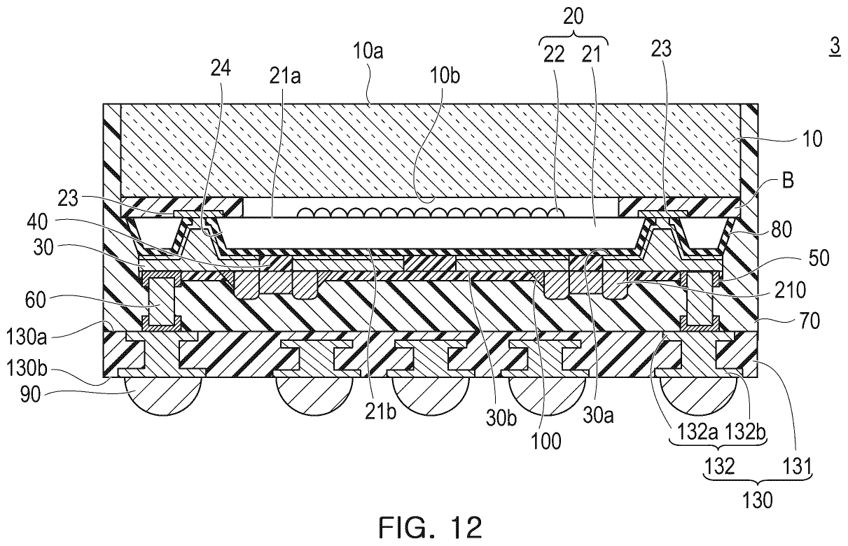

A semiconductor package 3 according to a third example embodiment may be described with reference to FIGS. 12 to 17. As for the semiconductor package 3, the same components as in the above-described example embodiments may be assigned with the same symbol, and the description thereof may not be provided. Also, the components not particularly mentioned may be configured the same as the above-described example embodiments.

The semiconductor package 3 may include a transparent substrate 10, a first semiconductor chip 20, a first redistribution layer 30, a second insulating layer 40, a first conductive portion 50, a columnar electrode 60, an encapsulating resin layer 70, a second insulating layer 80, a connection terminal 90, and a package substrate 130 as illustrated in FIG. 12. The semiconductor package 1 may be mounted on a mounting substrate (500 in FIG. 1) by interposing the connection terminal 90. The semiconductor package 3 may be different from the semiconductor package 2 of the second example embodiment in that a package substrate 130 is included instead of the second redistribution layer 110.

The package substrate 130 may be configured as, for example, a printed circuit board (PCB). The package substrate 130 may include an insulating portion 131 and an internal wiring portion 132.

The internal wiring portion 132 may have a first connection portion 132a and a second connection portion 132b. The package substrate 130 may have a first surface 130a exposing the first connection portion 132a as a first semiconductor chip 20 side, and a second surface 130b exposing the second connection portion 132b as an opposite side of the first surface 130a. The first connection portion 132a may expose at least only a connection opening portion with a connection portion of a connection target component (e.g., a second end 62 of a columnar electrode 60). The second connection portion 132b may expose at least a connection opening portion with a connection portion of a connection target component (e.g., an end of the connection terminal 90 on the package substrate 130 side).

The first connection portion 132a may be electrically connected to the second end 62 of the columnar electrode 60. The second connection portion 132b may be electrically connected to one or more connection terminals 90 laid out on the second surface 130b of the package substrate 130. That is, the internal wiring portion 132 may be electrically connected to the columnar electrode 60 through the first connection portion 132a and may be electrically connected to the connection terminal 90 laid out on the second surface 130b of the package substrate 130 through the second connection portion 132b. The second connection portion 132b may be formed depending on the arrangement position of the connection terminal 90. Accordingly, the connection terminal 90 may be laid out at a desired position on the second surface 130b of the package substrate 130. The connection terminal 90 may be electrically connected to the first passive component 210 or the first semiconductor chip 20 through the package substrate 130 and the columnar electrode 60.

The insulating portion 131 may be formed of or include a resin having insulation, such as a phenol resin, an epoxy resin, or a polyimide. The internal wiring portion 132 may have a wiring structure (e.g., a through-silicon via (TSV)) in which a first connection portion 132a and a second connection portion 132bare connected to each other. The first connection portion 132a and the second connection portion 132b may include metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or an alloy thereof.

In the semiconductor package 3 of the third example embodiment, the columnar electrode 60 may be disposed in the empty space (e.g., the outer circumferential side/portion of the second surface 30b of the first redistribution layer 30) of the first redistribution layer 30, similarly to the semiconductor package 2 of the second example embodiment. Accordingly, in the semiconductor package 3, the connection terminal 90 may be disposed regardless of the arrangement of the first passive component 210 to be mounted. Also, in the semiconductor package 3, desired the size of the connection terminal 90 may not need to be considered. Thus, the size of the columnar electrode 60 may be reduced. Also, in the semiconductor package 3, similarly to the semiconductor package 1 of the first example embodiment, an encapsulating resin layer 70 functioning as a stress alleviating layer may be formed to cover the first redistribution layer 30 and a portion of the columnar electrode 60. Accordingly, the semiconductor package 3 may become a package in which solder stress accompanying temperature changes during package mounting may be greatly reduced, thereby improving solder joint reliability during package mounting.

In the description below, a method of manufacturing a semiconductor package 3 may be described.

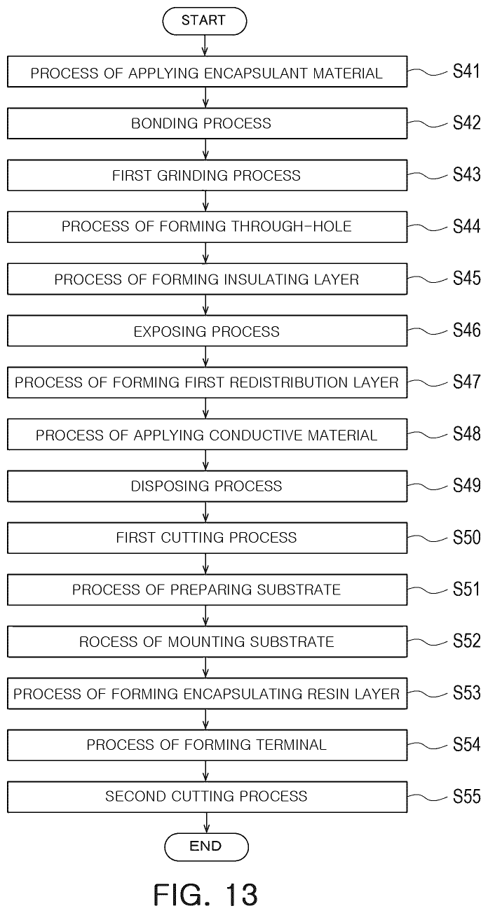

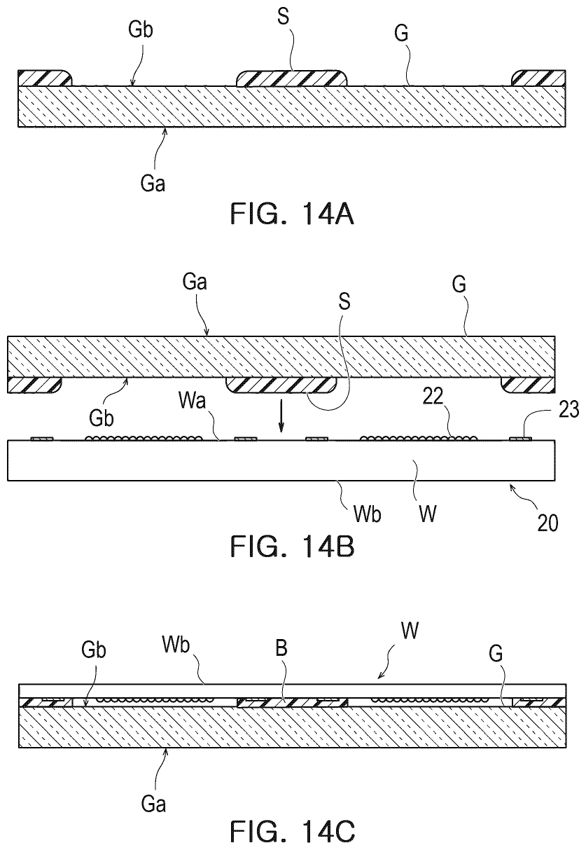

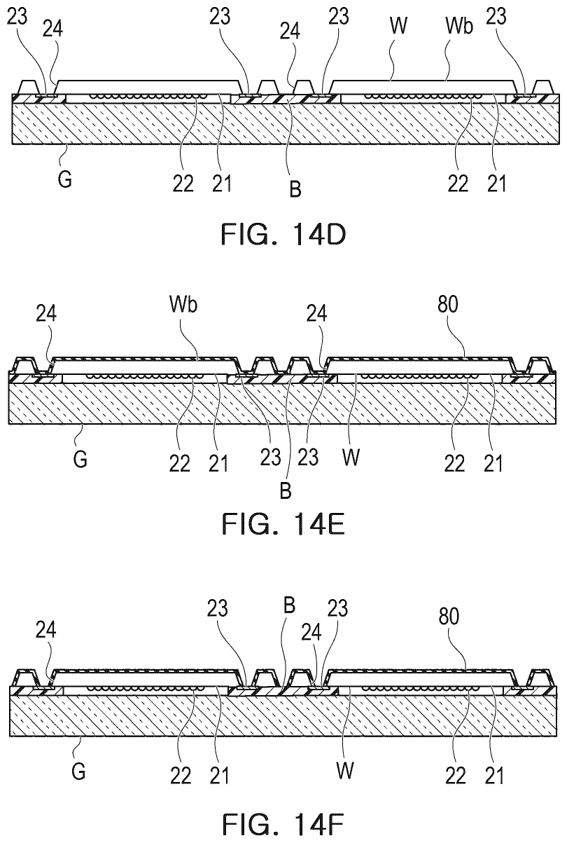

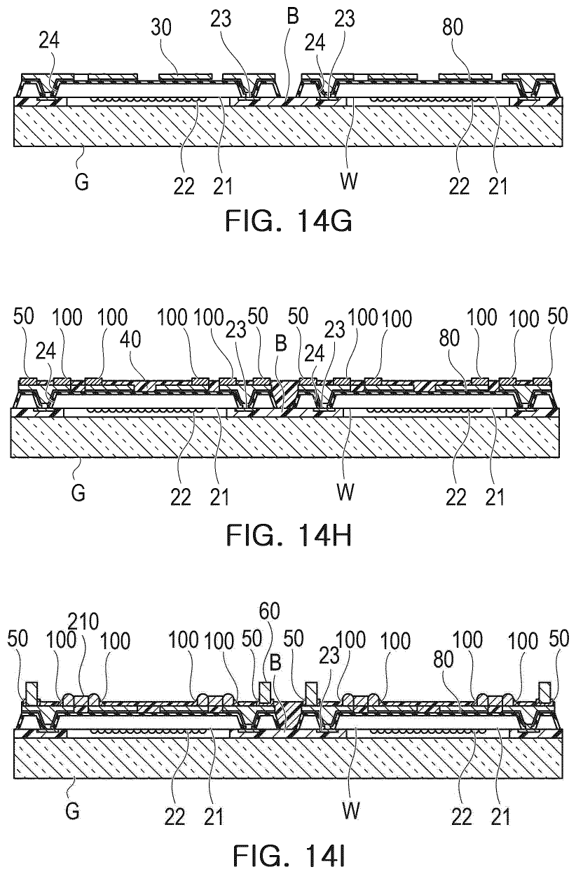

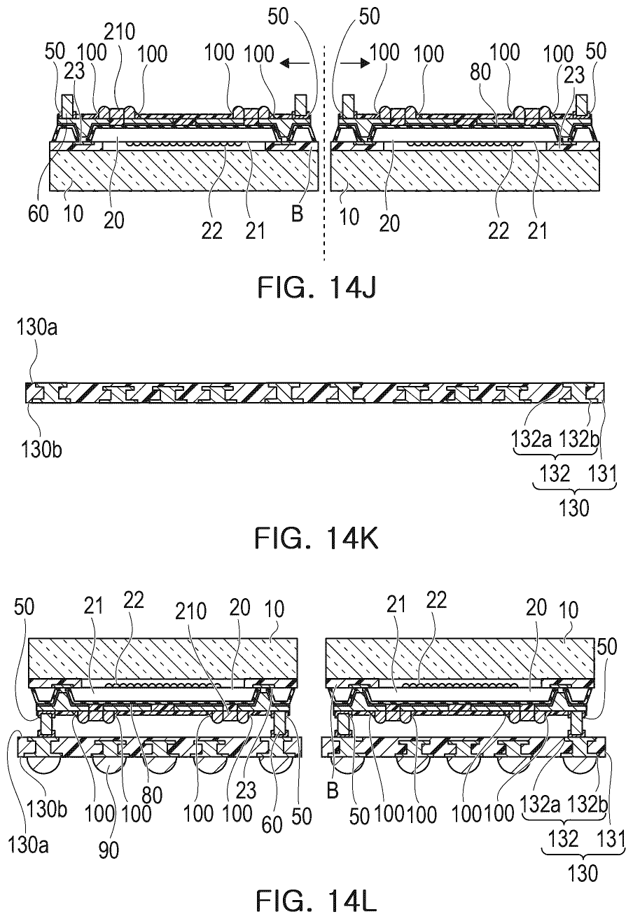

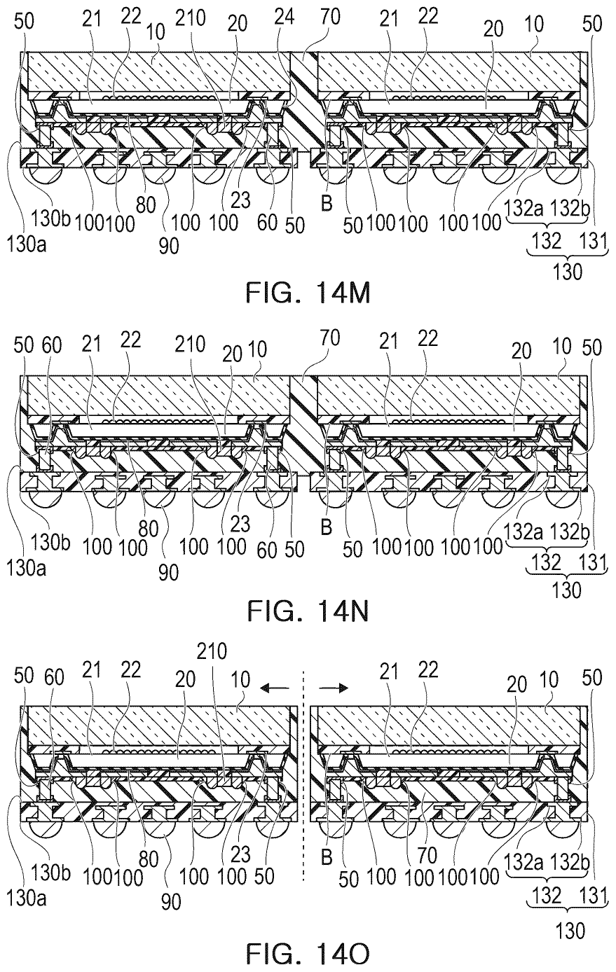

As illustrated in FIG. 13, a method of manufacturing a semiconductor package 3 may include a process of applying an encapsulant material (S41) as process 1, a boning process (S42) as process 2, a grinding process (S43) as process 3, a process of forming a through-hole (S44) as process 4, a process of forming an insulating layer (S45) as process 5, an exposing process (S46) as process 6, a process of forming a first redistribution layer (S47) as process 7, a process of applying a conductive material (S48) as process 8, a disposing process (S49) as process 9, a first cutting process (S50) as process 10, a process of preparing a substrate (S51) as process 11, a process of mounting a substrate (S52) as process 12, a process of forming an encapsulating resin layer (S53) as process 13, a process of forming a terminal (S54) as process 14, and a second cutting process (S55) as process 15. FIGS. 14A to 14O are diagrams illustrating each process (process 1 to process 15) included in the process of manufacturing the semiconductor package 3.

Process 1 may include a process of applying an encapsulant material (S41) of applying an encapsulant material S functioning as a bonding portion B to the second surface Gb opposing the first surface Ga of a glass substrate G that will become a transparent substrate 10 as illustrated in FIG. 14A. The encapsulant material S may be applied to include a periphery of each of the packages and a separated boundary portion.

Process 2 may include a boning process of bonding the second surface Gb of the glass substrate G applied with the encapsulant material S and the first surface Wa of the semiconductor wafer W that will become the chip substrate 21 of the first semiconductor chip 20 to oppose each other as illustrated in FIG. 14A. A boning process (S42) may be performed. The semiconductor wafer W may include components (e.g., on-chip lens 22, electrode 23, and other image sensors) mounted on the light-receiving region of each of packages of the first surface Wa. In process 2, a bonding portion B may be formed by performing a curing process on the encapsulant material S.

Process 3 may include a grinding process (S43) of back-grinding the second surface Wb of the semiconductor wafer W to a thickness of a desired (or alternatively, predetermined) chip size as illustrated in FIG. 14C.

Process 4 may include a process of forming a through-hole (S44) by etching from the second surface Wb of the semiconductor wafer W as illustrated in FIG. 14D. The through-hole 24 may be formed by a deep reactive-ion etching (DRIE) process. The through-hole 24 may be formed at the forming position of the electrode 23 or the boundary position of the package. By forming the through-hole 24, a portion of the electrode 23 and a portion of the bonding portion B of the boundary portion may be exposed.

Process 5 may include a process of forming an insulating layer (S45) for forming a second insulating layer 80 on the entire second surface Wb of the semiconductor wafer W as illustrated in FIG. 14E. The process of forming the second insulating layer 80 may be performed by a deposition method, a sputtering method, a CVD method, or the like.

Process 6 may include an exposing process (S46) of exposing a portion of the electrode 23 by removing the second insulating layer 80 positioned at the bottom portion of the through-hole 24 to expose a portion of the electrode 23, for electrical connection with another layer to be placed thereon later, as illustrated in FIG. 14F. The process of removing the second insulating layer 80 may be performed by an etching process, or the like.

Process 7 may include a process of forming a first redistribution layer (S47) of forming a first redistribution layer 30 on the second insulating layer 80 as illustrated in FIG. 14G. The first redistribution layer 30 may be formed so as to be electrically connected to the electrode 23 using a photolithography method and a plating method.

Process 8 may include a process of applying a conductive material (S48) of forming a first conductive portion 50 and a second conductive portion 100 by applying a conductive paste as a conductive material as illustrated in FIG. 14H. Also, in process 8, the first conductive portion 50, the second conductive portion 100, and the first redistribution layer 30 formed in this process may be electrically connected to each other, such that the first insulating layer 40 may be formed in advance in an opening region other than the forming region of each conductive portion. The first conductive portion 50 may be formed on the first redistribution layer 30 corresponding to the arrangement position of the columnar electrode 60. The second conductive portion 100 may be formed on the first redistribution layer 30 corresponding to the arrangement position of the first passive component 210. The process of forming the first conductive portion 50 and the second conductive portion 100 may be performed by a screen-printing method, an inkjet printing method, or the like, in a state in which a mask is disposed in a region other than the forming position. In process 8, the conductive material may be a conductive paste, or solder may be used. In some example embodiments, different materials may be used for the first conductive portion 50 and the second conductive portion 100.

Process 9 may include a disposing process (S49) of disposing the columnar electrode 60 and the first passive component 210 as illustrated in FIG. 14I. The process of disposing the columnar electrode 60 may be similar to the ball mounting method and may be performed by a process of disposing a mask in a region other than the first conductive portion 50 such that the first conductive portion 50 as illustrated in FIG. 14H is exposed, a process of returning a plurality of metal pins (e.g., copper pins) that will become the columnar electrode 60 on the mask while disposing and allowing the metal pins (e.g., copper pins) to be in contact with each of the first conductive portions 50 from the opening portion of the mask, and a process of removing the mask and drying, firing, and curing the first conductive portion 50. The end of the columnar electrode 60 in contact with the first conductive portion 50 may be the first end 61. The first passive component 210 may be mounted on the first redistribution layer 30 by a general mounting process (e.g., a mounting process by a mounting device, or the like). Also, process 9 may also include a process of reflowing the conductive material. By the reflow process, the columnar electrode 60 and the first passive component 210 may be fixed to the first redistribution layer 30.

In process 9, the columnar electrode 60 and the first passive component 210 may be mounted in the same process, but example embodiments thereof are not limited thereto, and the columnar electrode 60 and the first passive component 210 may be mounted in different processes, respectively. Also, as for the process of reflowing the conductive material, process different from process 9 may be performed.

Process 10 may include a first cutting process (S50) of cutting a desired (or alternatively, predetermined) region of a semiconductor wafer W and singulating a first semiconductor chip 20 of a semiconductor package 3 as illustrated in FIG. 14J. Accordingly, the semiconductor package 3 before encapsulating may be formed individually.

Process 11 may include a process of preparing a substrate (S51) for preparing a package substrate 130 and applying a conductive material to a first connection portion 132a corresponding to a mounting position of a semiconductor package 3 before encapsulating as illustrated in FIG. 14K. The conductive material may be applied by a screen-printing method or an inkjet printing method while disposing a mask in a region other than the forming position. In process 11, the conductive material may be a solder or a conductive paste, similarly to the forming material of the first conductive portion 50.

Process 12 may include a process of mounting a substrate (S52) for mounting the semiconductor package 3, which is singulated in process 10, before encapsulation on a first surface 130a of a package substrate 130 as illustrated in FIG. 14L. The semiconductor package 3 before encapsulation may be mounted such that the second end 62 of the columnar electrode 60 may be electrically connected to the first connection portion 132a formed on the first surface 130a of the package substrate 130. The semiconductor package 3 before encapsulation may be mounted on the package substrate 130 by a general mounting process (e.g., a mounting process by a mounting device, or the like). Also, process 12 may also include a process of reflowing a conductive material. The semiconductor package 3 before encapsulation may be fixed to the package substrate 130 by the reflow process. In process 12, the reflow process of the conductive material may be performed as a separate process.

Process 13 may include a process of forming an encapsulating resin layer (S53) for forming an encapsulating resin layer 70 as illustrated in FIG. 14M. The encapsulating resin layer 70 may be formed by filling an encapsulation space with an encapsulating resin including a non-conductive filler such as an epoxy resin. Also, the encapsulating resin layer 70 may be applied so as to cover the first passive component 210. Accordingly, the encapsulating resin layer 70 may be formed so as to cover a side surface of the first conductive portion 50, a side surface of the columnar electrode 60, the first redistribution layer 30, and the first passive component 210.

Process 14 may include a process of forming a terminal (S54) for forming a connection terminal 90 on the second connection portion 132b of the package substrate 130 as illustrated in FIG. 14N. The process of forming the connection terminal 90 may be performed by a ball mounting method, a screen-printing method, or the like. In process 14, the level position of the contact surface of the connection terminal 90 with respect to the mounting substrate (500 in FIG. 1) may be formed to be almost the same position in the thickness direction of the semiconductor package 3 from the viewpoint of ease of mounting.

Process 15 may include a second cutting process (S55) for cutting a desired (or alternatively, predetermined) region of the encapsulating resin layer 70 and singulating the semiconductor package 2 as illustrated in FIG. 14O. Through the above process, the semiconductor package 3 illustrated in FIG. 12 may be manufactured.

The method of manufacturing a semiconductor package 3 described above may include a process for performing other processes than process 1 to process 15 if desired (e.g., a process for performing a cleaning process, or the like). Also, in the method of manufacturing a semiconductor package 3, the order of performing the processes may be appropriately modified and performed within a range in which the configuration and function of the manufactured semiconductor package 2 do not deviate from the gist of the present disclosure.

Also, in the manufacturing method described above, in the semiconductor package 3, a connection terminal 90 may not be formed in the second connection portion 132b of the package substrate 130. In this case, process 14 may not be performed.

According to some modified example embodiments of the second example embodiment, the semiconductor package 3 may be configured as below.

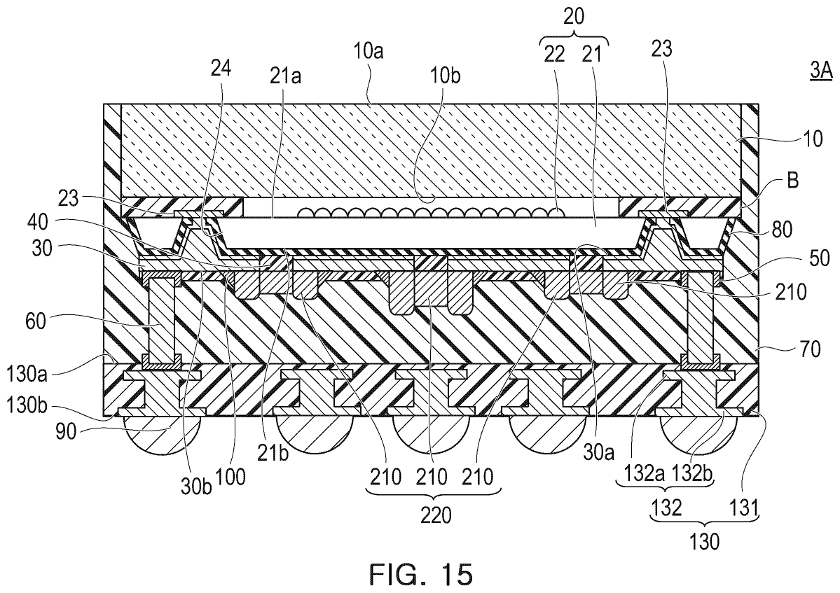

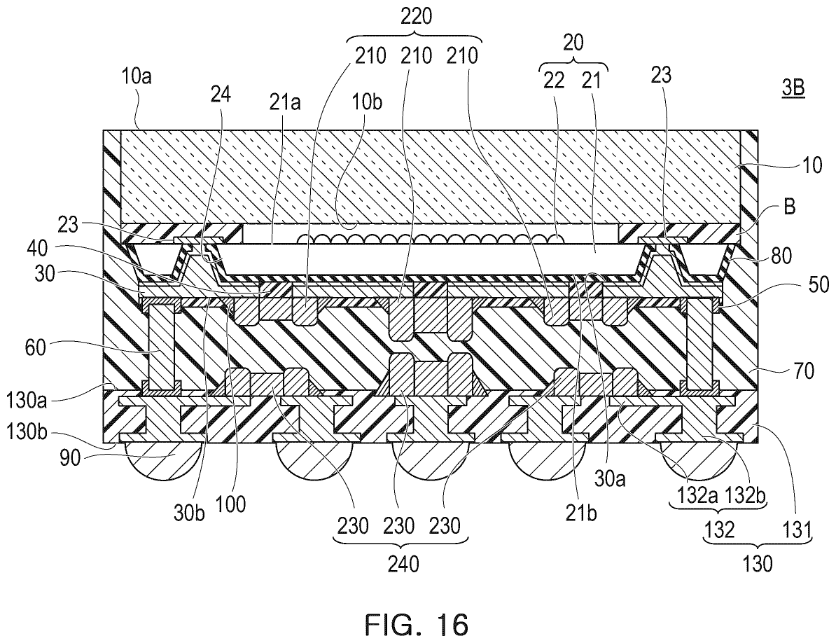

FIGS. 15 and 16 illustrate semiconductor packages 3A and 3B, which are modified examples of the third example embodiment. In the semiconductor package 3A, a first passive component group 220 including a plurality of first passive components 210 having different levels may be mounted in the encapsulation space between the first redistribution layer 30 and the package substrate 130 as illustrated in FIG. 15. In the semiconductor package 3A, a first passive component 210 (e.g., a first surface of the first passive component 210 opposite to a second surface of the first passive component 210 that is facing or in contact with the first redistribution layer 30) having a relatively low level with respect to the second surface 30b of the first redistribution layer 30 among the first passive component group 220 may be disposed on an outer circumferential side (e.g., a circumferential portion) of the first semiconductor chip 20 in a cross-section. Also, in the semiconductor package 3A, a first passive component 210 (e.g., a first surface of the first passive component 210 opposite to a second surface of first passive component 210 that is facing or in contact with the first redistribution layer 30) having a relatively high level with respect to the second surface 30b of the first redistribution layer 30 may be disposed on a central portion of the first semiconductor chip 20 in a cross-section. In other words, the first passive component group 220 (e.g., one or more first passive components 220) may include one type of passive component having a first height and another type of passive component having a second height greater than the first height and the one type of passive component may be on an outer circumferential portion of the first semiconductor chip 20, and the another type of passive component may be on a central portion of the first semiconductor chip 20.

In the semiconductor package 3B, electronic components may be mounted on the package substrate 130 in addition to the first redistribution layer 30 as illustrated in FIG. 16. In the semiconductor package 3B, a second passive component group 240 including a plurality of second passive components 230 (e.g., first surfaces of the plurality of second passive components 230 opposite to second surfaces of the plurality of second passive component 230 that are facing or in contact with the first connection portion 132a of the internal wiring portion 132) having different levels with respect to the first surface 130a of the package substrate 130 may be mounted on the package substrate 130 with respect to the form illustrated in FIG. 16. In the semiconductor package 3B, a first passive component 210 (e.g., a first surface of the first passive component 210 opposite to a second surface of the first passive component 210 that is facing or in contact with the first redistribution layer 30) having a relatively lower level with respect to the second surface 30b of the first redistribution layer 30, from among the first passive component group 220, may be disposed on an outer circumferential side (e.g., an outer circumferential portion) of the first semiconductor chip 20 in a cross-section, and a first passive component 210 (e.g., a first surface of the first passive component 210 opposite to a second surface of the first passive component 210 that is facing or in contact with the first redistribution layer 30) having a higher level with respect to the second surface 30b of the first redistribution layer 30, from among the first passive component group 220, may be disposed on a central portion of the first semiconductor chip 20 in a cross-section. In the semiconductor package 3B, from among the second passive component group 240, a second passive component 230 (e.g., a first surface of the second passive component 230 opposite to a second surface of the second passive component 230 that is facing or in contact with the first connection portion 132a of the internal wiring portion 132) having a relatively low level with respect to the first surface 130a of the package substrate 130 may be disposed on the outer circumferential side (e.g., an outer circumferential portion) of the first semiconductor chip 20 in a cross-section, and another second passive component 230 (e.g., a first surface of the another second passive component 230 opposite to a second surface of the another second passive component 230 that is facing or in contact with the first connection portion 132a of the internal wiring portion 132) having a relatively high level with respect to the first surface 130a of the package substrate 130 may be disposed on the central portion of the first semiconductor chip 20 in a cross-section. In other words, the second passive component group 240 (e.g., one or more second passive components 240) may include one type of passive component having a first height and another type of passive component having a second height greater than the first height and the one type of passive component may be on an outer circumferential portion of the first semiconductor chip 20, and the another type of passive component may be on a central portion of the first semiconductor chip 20.

As illustrated in FIG. 15 or 16, in the semiconductor package 3A and 3B, by arranging the first passive component 210 or the second passive component 230 in the same manner as illustrated, the flow of the encapsulating resin filled in the encapsulation space in the formation of the encapsulating resin layer 70 may be reduced or prevented from being impeded by the first passive component 210 having a relative high level. Accordingly, the semiconductor packages 3A and 3B may reduce voids after the encapsulating resin layer 70 is formed.

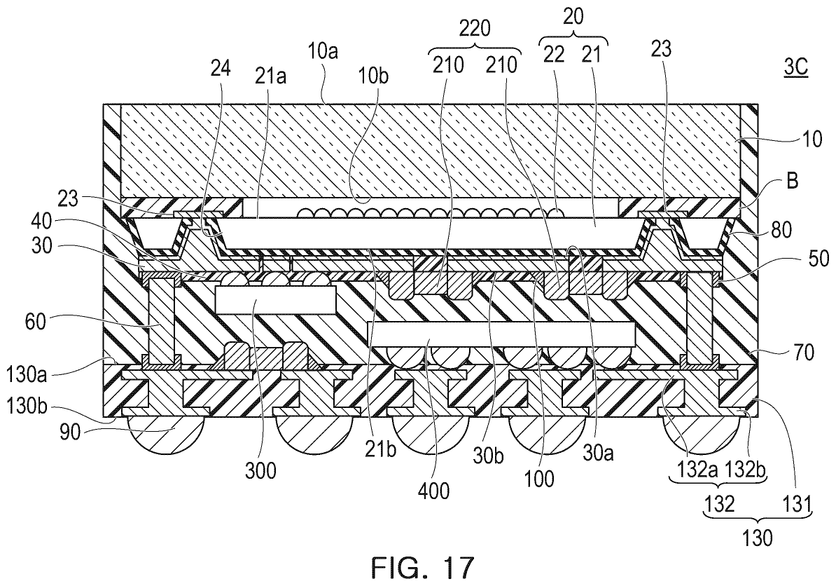

FIG. 17 illustrates a semiconductor package 3C, which is another modified example of the third example embodiment. In the semiconductor package 3C, the first passive component 210 and the second semiconductor chip 300 may be mounted on the second surface 30b of the first redistribution layer 30, and the second passive component 230 and the third semiconductor chip 400 may be mounted on the first surface 130a of the package substrate 130. In the semiconductor package 3C, other electronic components, such as a second semiconductor chip 300 may be mounted in addition to one or more first passive components 210 on the second surface 30b of the first redistribution layer 30. In addition to one or more second passive components 230 on the second surface 130b of the package substrate 130, in the semiconductor package 3C, other electronic components, such as a third semiconductor chip 400 may be mounted. By this configuration, semiconductor package 3B may be more highly functionalized. In the semiconductor package 3C, the second semiconductor chip 300 may be mounted on the first redistribution layer 30, and the third semiconductor chip 400 may be mounted on the package substrate 130, but in some example embodiments, the semiconductor chips may be mounted in only one direction.

A camera module including a semiconductor package according to an example embodiment may be described.

FIG. 18 illustrates a camera module 600 including a semiconductor package according to an example embodiment of the present disclosure. The camera module 600 illustrated in FIG. 18 may be configured to include the semiconductor package 1 of the first example embodiment. The camera module 600 is not limited to the semiconductor package 1 and may be mounted in the same manner with respect to modified examples of each form in addition to the semiconductor package 2 of the second example embodiment and the semiconductor package 3 of the third example embodiment.

The camera module 600 may include at least an optical unit 610 including a lens unit 620. The camera module 600 may be mounted on an electronic device such as a camera or a portable terminal, which is not illustrated. The camera module 600 may have other electronic components and mechanical structures, or the like, in addition to the optical unit 610.

The optical unit 610 may collect light from a subject and may guide light to a first semiconductor chip 20, which is a solid imaging device. The optical unit 610 may include a lens unit 620 including a plurality of lenses. In addition to the lens unit 620, the optical unit 610 may include an actuator for implementing at least one of an autofocusing function or an optical image stabilization function. The optical unit 610 may be configured as a simple lens holder not having the autofocusing or the optical image stabilization function. In this case, the autofocusing and the optical image stabilization functions may be implemented by image processing, or the like.

The camera module 600 may reduce the mounting region of electronic components such as passive components (first passive component 210, or the like) or one or more semiconductor chips mounted in the module by including at least one of the semiconductor packages 1, 1A, 1B, 2, 2A, 2B, 3, 3A and 3B, or 3C manufactured on the wafer level. Accordingly, when the lens unit 620 of the camera module 700 is manufactured on the wafer level, the entire module may be manufactured on the wafer level.

As described above, the semiconductor package 1 according to an example embodiment may include a first semiconductor chip 20 having an electrode 23 formed on a first surface 21a of a chip substrate 21 having a first surface 21a to which light is incident, and a second surface 21 b which is an opposite side to the first surface 20 a, a through-hole 24 extending from the second surface 21b of the chip substrate 21 to the electrode 23, a first redistribution layer 30 formed on the second surface 21b of the chip substrate 21 and electrically connected to the electrode 23 by interposing the through-hole 24, one or more first passive components 210 electrically connected to the first redistribution layer 30, a columnar electrode 60 electrically connected to the first redistribution layer 30, and an encapsulating resin layer 70 covering the second surface 21b of the chip substrate 21. The first redistribution layer 30 may have a first surface 30a which becomes the first semiconductor chip 20 side, and a second surface 30b which is an opposite side to the first surface 30a, the columnar electrode 60 may be disposed on the second surface 30b of the first redistribution layer 30, and the first passive component 210 may be disposed in a position lower than the level of the columnar electrode 60 with respect to the second surface 30b of the first redistribution layer 30, and may be covered with an encapsulating resin layer 70.

A camera module 600 according to an example embodiment may include an optical unit 610 having at least the semiconductor package 1 and a lens unit 620 disposed on a side of the semiconductor package 1 to which light is incident.

The semiconductor package 1 may have an encapsulating resin layer 70 formed to function as a stress alleviating layer to cover the first redistribution layer 30 and a portion of the columnar electrode 60. Accordingly, the semiconductor package 1 may become a package in which solder stress due to temperature change during package mounting is greatly reduced and solder joint reliability during package mounting is improved. Also, in the semiconductor package 1, a passive component mounted in the camera module 600 may be mounted in the semiconductor package 1 as the first passive component 210. Accordingly, in the camera module 600, the module size may be reduced, and the distance between the semiconductor package 1 and the first passive component 210 may be shortened, thereby improving electrical properties.

According to the aforementioned example embodiments, as for the semiconductor package, by reducing solder stress caused by temperature changes during package mounting, solder joint reliability may improve. Also, in the semiconductor package, the module size of the camera module to be mounted may be reduced. Also, the semiconductor package may obtain improved electrical properties with passive components mounted on the camera module.

Also, the camera module may include the semiconductor package according to some example embodiments, the module size may be reduced, and improved electrical properties with the passive components mounted thereon may be obtained.

According to an example embodiment, a method of manufacturing a semiconductor package may include applying an encapsulant material on to a first surface of a glass substrate, bonding the first surface of the glass substrate to a third surface of a semiconductor wafer, the semiconductor wafer including an electrode on the third surface, forming a through-hole to penetrate through the semiconductor wafer, forming an insulating layer on a fourth surface of the semiconductor wafer while exposing a portion of the electrode in the through-hole, the fourth surface being opposite to the third surface, forming a redistribution layer on the insulating layer to be electrically connected to the electrode, applying a conductive material to form a first conductive portion and a second conductive portion on the redistribution layer, disposing a columnar electrode on the first conductive portion and disposing a first passive component on the second conductive portion, forming an encapsulating resin layer to cover the first passive component and to expose a fifth end of the columnar electrode, forming a terminal on a sixth end of the columnar electrode, the sixth end being opposite to the fifth end, and cutting the semiconductor wafer to provide the semiconductor package.

The method may further include grinding the fourth surface of the semiconductor wafer to a desired thickness between the bonding and the forming the through-hole.

The forming the insulating layer may further include removing a portion of the insulating layer positioned at a bottom of the through-hole to expose the electrode in the through-hole.

While some example embodiments have been illustrated and described above, it will be configured as apparent to those skilled in the art that modifications and variations could be made without departing from the scope of the present disclosure as defined by the appended claims.

What is claimed is:

1. A semiconductor package, comprising:
a first semiconductor chip including a chip substrate, the chip substrate including a first surface and a second surface opposite to the first surface, the first semiconductor chip including an electrode on the first surface and a through-hole extending from the second surface to the first surface to expose the electrode;
a first redistribution layer on the second surface of the chip substrate, the first redistribution layer being in the through-hole and electrically connected to the electrode, the first redistribution layer including a third surface facing the first semiconductor chip and a fourth surface opposite to the third surface;
one or more first passive components electrically connected to the first redistribution layer, each of the one or more first passive components including a fifth surface facing the first redistribution layer and a sixth surface opposite to the first surface;
a columnar electrode electrically connected to the first redistribution layer, the columnar electrode including a seventh surface facing the first redistribution layer and an eighth surface opposite to the seventh surface; and
an encapsulating resin layer covering the second surface of the chip substrate,
wherein the columnar electrode is on the fourth surface of the first redistribution layer, and
wherein the sixth surface of each of the one or more first passive components is at a position lower than the eighth surface of the columnar electrode with respect to the fourth surface of the first redistribution layer and is covered by the encapsulating resin layer.

2. The semiconductor package of claim 1, wherein, when the one or more first passive components include one type of passive component having a first height and another type of passive component having a second height greater than the first height, and the one type of passive component is on an outer circumferential portion of the first semiconductor chip.

3. The semiconductor package of claim 1, wherein a second semiconductor chip is on the fourth surface of the first redistribution layer.

4. The semiconductor package of claim 1, further comprising:
a second redistribution layer on an external surface of the encapsulating resin layer and electrically connected to the columnar electrode, the second redistribution layer including a nineth surface facing the first semiconductor chip and a tenth surface opposite to the nineth surface, and
a plurality of connection terminals on the tenth surface.

5. The semiconductor package of claim 1, further comprising:
a package substrate electrically connected to the columnar electrode, the package substrate including an eleventh surface and a twelfth surface opposite to the eleventh surface, and
a connection terminal on the twelfth surface of the package substrate,
wherein the package substrate includes an insulating portion and an internal wiring portion in the insulating portion,
wherein the internal wiring portion has a first connection portion exposed to the eleventh surface of the package substrate and a second connection portion exposed to the twelfth surface of the package substrate, and
wherein the internal wiring portion is electrically connected to the columnar electrode through the first connection portion and is electrically connected to the connection terminal through the second connection portion.

6. The semiconductor package of claim 5, further comprising:
one or more second passive components on the eleventh surface of the package substrate and connected to the internal wiring portion.

7. The semiconductor package of claim 6,
wherein the one or more second passive components include one type of passive component having a first height and another type of passive component having a second height greater than the first height, and
wherein the one type of passive component is on an outer circumferential portion of the first semiconductor chip.

8. The semiconductor package of claim 5, wherein a third semiconductor chip is on the eleventh surface of the package substrate.

9. The semiconductor package of claim 1, wherein the columnar electrode adheres to the first redistribution layer with a first conductive portion interposed therebetween.

10. The semiconductor package of claim 9, wherein a first elastic modulus of the first conductive portion is lower than a second elastic modulus of the columnar electrode.

11. The semiconductor package of claim 1, wherein the columnar electrode includes a metal pin or a plated metal.

12. The semiconductor package of claim 1, wherein the encapsulating resin layer includes a non-conductive filler.

13. The semiconductor package of claim 1, wherein a first coefficient of linear expansion of the encapsulating resin layer is equal to or higher than a second coefficient of linear expansion of the chip substrate of the first semiconductor chip.

14. The semiconductor package of claim 9, wherein the first conductive portion includes conductive paste or solder.

15. The semiconductor package of claim 1, wherein the first semiconductor chip is an image sensor.

16. A camera module, comprising:
the semiconductor package in claim 1; and
an optical unit having at least one lens unit on a side of the semiconductor package to which the light is incident.

17. A semiconductor package, comprising:
a first semiconductor chip including a chip substrate, the chip substrate including a first surface and a second surface opposite to the first surface, the first semiconductor chip including an electrode on the first surface and a through-hole extending from the second surface to the first surface to expose the electrode;
a first redistribution layer on the second surface of the chip substrate, the first redistribution layer being in the through-hole and electrically connected to the electrode, the first redistribution layer including a third surface facing the first semiconductor chip and a fourth surface opposite to the third surface;
one or more passive components on the fourth surface of the first redistribution layer and electrically connected to the first redistribution layer;
a columnar electrode on the fourth surface of the first redistribution layer and electrically connected to the first redistribution layer; and
an encapsulating resin layer on the second surface of the chip substrate,
wherein a first height of each of the one or more passive components is less than a second height of the columnar electrode and the encapsulating resin layer covers the one or more passive components and surrounds the columnar electrode.

18. The semiconductor package of claim 17, wherein the one or more passive components includes a first passive component having a first height on a central portion of the first semiconductor chip and a second passive component having a second height greater than the first height on an outer circumferential portion of the first semiconductor chip.

19. The semiconductor package of claim 17, further comprising:
a connection terminal in physical contact with the columnar electrode exposed by the encapsulating resin layer.

20. The semiconductor package of claim 17, further comprising:
a conductive portion interposed between and in direct contact with the columnar electrode and the first redistribution layer.
